(19) United States
(12) Patent Application Publication
(10) Pub. No.: US 2011/0189610 A1
(43) Pub. Date: Aug. 4, 2011

(54) PHOTORESIST COMPOSITION

(75) Inventors: Nobuo ANDO, Toyonaka-shi (JP); Ichiki TAKEMOTO, Kawanishi-shi (JP)

(73) Assignee: SUMITOMO CHEMICAL COMPANY, LIMITED, Tokyo (JP)

(21) Appl. No.: 13/018,457

(22) Filed: Feb. 1, 2011

(30) Foreign Application Priority Data
Feb. 4, 2010 (JP) 2010-022920

(51) Int. Cl. G03F 7/20; G03F 7/004

(52) U.S. Cl. 430/270.1; 430/325

(57) ABSTRACT

The present invention provides a photoresist composition comprising a compound represented by the formula (I):

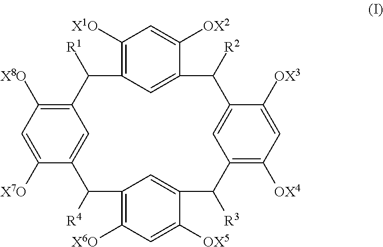

wherein R¹, R², R³ and R⁴ independently represent a hydrogen atom etc., X¹ to X⁸ independently represent a hydrogen atom or a group represented by the formula (II):

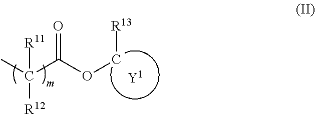

wherein R¹¹ and R¹² independently represent a hydrogen atom etc., m represents an integer of 1 to 4, R¹³ represents a C1-C6 alkyl group etc., and ring Y¹ represents a C3-C20 saturated hydrocarbon ring, and an acid generator represented by the formula (B1):

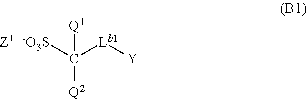

wherein Q¹ and Q² independently represent a fluorine atom etc., L^{b1} represents a C1-C17 saturated divalent hydrocarbon group in which one or more —CH₂— can be replaced by —O— or —CO—, Y represents a C1-C18 aliphatic hydrocarbon group etc., and Z⁺ represents an organic cation.

This nonprovisional application claims priority under 35 U.S.C. §119(a) on Patent Applications No. 2010-022920 filed in JAPAN on Feb. 4, 2010, the entire contents of which are hereby incorporated by reference.

### FIELD OF THE INVENTION

The present invention relates to a photoresist composition.

### BACKGROUND OF THE INVENTION

A photoresist composition is used for semiconductor microfabrication.

In semiconductor microfabrication, it is desirable to form patterns having high resolution, high sensitivity and good line-edge roughness, and it is expected for a chemically amplified resist composition to give such patterns.

US 2008/0248417 A1 discloses a photoresist composition containing a compound wherein at least one hydroxyl group of 2,6-bis[4-hydroxy-3-(2-hydroxy-5-methylbenzyl)-2,5-dimethylbenz yl]-4-methylphenol is protected by a 2-methyl-2-adamantyloxycarbonylmethyl group.

### SUMMARY OF THE INVENTION

An object of the present invention is to provide a novel photoresist composition.

This and other objects of the present invention will be apparent from the following description.

The present invention relates to the followings:

<1> A photoresist composition comprising a compound represented by the formula (I):

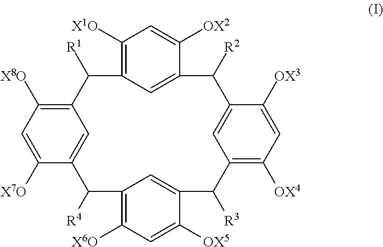

wherein R¹, R², R³ and R⁴ independently represent a hydrogen atom, a C1-C6 alkyl group, a C3-C10 cycloalkyl group, a C4-C20 cycloalkylalkyl group, a C6-C20 aryl group, a C7-C20 aralkyl group or a group represented by —OX⁹, and one or more hydrogen atoms of the alkyl group, the aryl group and the aralkyl group can be replaced by a group represented by —OX¹⁰, X¹, X², X³, X⁴, X⁵, X⁶, X⁷, X⁸, X⁹ and X¹⁰ independently represent a hydrogen atom or a group represented by the formula (II):

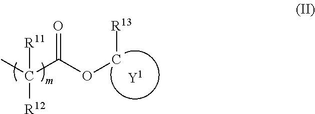

wherein R¹¹ and R¹² independently represent a hydrogen atom or a C1-C6 alkyl group, m represents an integer of 1 to 4, R¹³ represents a C1-C6 alkyl group or a C3-C12 saturated cyclic hydrocarbon group, and ring Y¹ represents a C3-C20 saturated hydrocarbon ring, and an acid generator represented by the formula (B1):

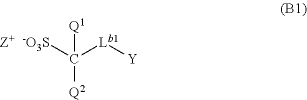

wherein Q¹ and Q² independently represent a fluorine atom or a C1-C6 perfluoroalkyl group, L^{b1} represents a single bond or a C1-C17 saturated divalent hydrocarbon group in which one or more —CH₂— can be replaced by —O— or —CO—, Y represents a C1-C18 aliphatic hydrocarbon group or a C3-C18 saturated cyclic hydrocarbon group, and the aliphatic hydrocarbon group and the saturated cyclic hydrocarbon group can have one or more substituents, and one or more —CH₂— in the aliphatic hydrocarbon group and the saturated cyclic hydrocarbon group can be replaced by —O—, —CO— or —SO₂—, and Z⁺ represents an organic cation;
<2> The photoresist composition according to <1>, wherein at least one selected from the group consisting of X¹, X², X³, X⁴, X⁵, X⁶, X⁷ and X⁸ is the group represented by the formula (II);
<3> The photoresist composition according to <1> or <2>, wherein the molecular weight of the compound represented by the formula (I) is 300 to 5,000;
<4> A process for producing a photoresist pattern comprising the following steps (1) to (5):

(1) a step of applying the photoresist composition according to <1>, <2> or <3> onto a substrate,

(2) a step of forming a photoresist film by conducting drying,

(3) a step of exposing the photoresist film to radiation,

(4) a step of baking the exposed photoresist film, and

(5) a step of developing the baked photoresist film with an alkaline developer, thereby forming a photoresist pattern;

<5> Use of the photoresist composition according to <1>, <2> or <3> for producing a photoresist pattern using an electron beam lithography system or an extreme ultraviolet lithography system.

### DESCRIPTION OF PREFERRED EMBODIMENTS

The photoresist composition of the present invention comprises a compound represented by the formula (I):

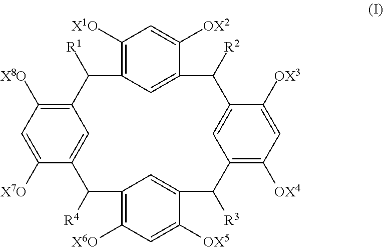

(hereinafter, simply referred to as COMPOUND (I)), and an acid generator represented by the formula (B1):

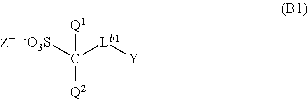

(hereinafter, simply referred to as Acid Generator (B1)).

In the formula (I), R¹, R², R³ and R⁴ independently represent a hydrogen atom, a C1-C6 alkyl group, a C3-C10 cycloalkyl group, a C4-C20 cycloalkylalkyl group, a C6-C20 aryl group, a C7-C20 aralkyl group or a group represented by —OX⁹.

Examples of the C1-C6 alkyl group include a methyl group, an ethyl group, a propyl group, an isopropyl group, a butyl group, an isobutyl group, an sec-butyl group, a tert-butyl group, a pentyl group, a neopentyl group, a tert-pentyl group, a 1-methylbutyl group, a hexyl group, an isohexyl group, a 1-methylpentyl group, a 2-methylpentyl group, a 3-methylpentyl group, a 1-ethylbutyl group, a 2-ethylbutyl group, a 3-ethylbutyl group, a 1,1-dimethylbutyl group and a 1-methyl-2-ethylpropyl group, and a C1-C4 alkyl group is preferably and a methyl group, an ethyl group, an isopropyl group and a butyl group are more preferable.

Examples of the C3-C10 cycloalkyl group include a cyclopropyl group, a cyclobutyl group, a cyclopentyl group, a cyclohexyl group, a cycloheptyl group, a cyclooctyl group, a cyclononyl group and a cyclodecyl group.

Examples of the C4-C20 cycloalkylalkyl group include a cyclopropylmethyl group, a cyclopropylethyl group, a cyclobutylmethyl group, a cyclobutylpropyl group, a cyclopentylmethyl group, a cyclopentylethyl group, a cyclopentylbutyl group, a cyclohexylmethyl group, a cyclohexylethyl group, a cyclohexylbutyl group, a cyclohexylpentyl group, a cyclohexylhexyl group, a cycloheptyloctyl group, a cyclooctyldecyl group, a cyclononyldodecyl group and a cyclodecylheptyl group.

Examples of the C6-C20 aryl group include a phenyl group, and examples of the C7-C21 aralkyl group include a benzyl group and a phenylethyl group.

Examples of the group represented by —OX⁹ wherein X⁹ represents a hydrogen atom or a group represented by the formula (II):

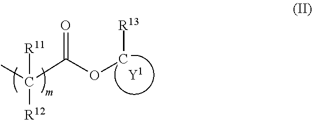

include a hydroxyl group and a group represented by the formula (IIa):

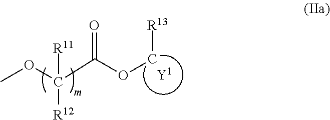

One or more hydrogen atoms of the alkyl group, the aryl group and the aralkyl group can be replaced by a group represented by —OX¹⁰ wherein X¹⁰ represents a hydrogen atom or the group represented by the formula (II).

Examples of the alkyl group in which one or more hydrogen atoms are replaced by a group represented by —OX¹⁰ wherein X¹⁰ represents a hydrogen atom include a hydroxymethyl group, a hydroxyethyl group, a hydroxypropyl group, a hydroxypentyl group, a hydroxylhexyl group and a 3-hydroxybutyl group. Examples of the aryl group in which one or more hydrogen atoms are replaced by a group represented by —OX¹⁰ wherein X¹⁰ represents a hydrogen atom include a hydroxyphenyl group, a dihydroxyphenyl group and a trihydroxyphenyl group. Examples of the aralkyl group in which one or more hydrogen atoms are replaced by a group represented by —OX¹⁰ wherein X¹⁰ represents a hydrogen atom include a hydroxybenzyl group.

Preferable examples of R¹, R², R³ and R⁴ include a hydrogen atom, a methyl group, an ethyl group, an isopropyl group, a butyl group, a hydroxylmethyl group, a hydroxyethyl group, a cyclopentyl group, a cylohexyl group, a phenyl group, a hydroxyphenyl group, a dihydroxyphenyl group, a methyl group having the group represented by the formula (IIa), an ethyl group having the group represented by the formula (IIa), a phenyl group having the group represented by the formula (IIa) and a phenyl group having the two groups represented by the formula (IIa).

In the formula (II), R¹¹ and R¹² independently represent a hydrogen atom or a C1-C6 alkyl group, m represents an integer of 1 to 4, R¹³ represents a C1-C6 alkyl group or a C3-C12 saturated cyclic hydrocarbon group, and ring Y¹ represents a C3-C20 saturated hydrocarbon ring. Examples of the C1-C6 alkyl group include the same as described above. Examples of the C3-C12 saturated cyclic hydrocarbon group include the C3-C10 cycloalkyl group described above and the followings:

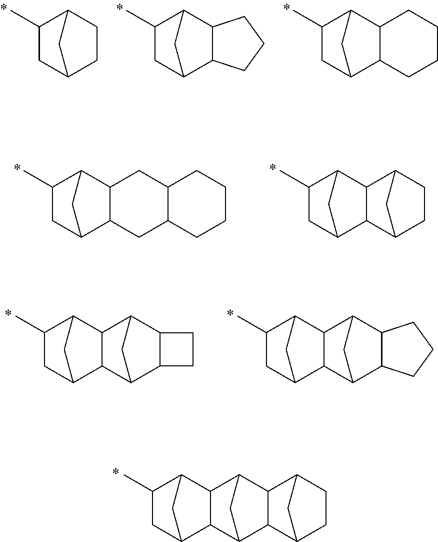

wherein * represents a binding position to the carbon atom to which R¹³ is bonded.

It is preferred that R¹¹ and R¹² independently represent a hydrogen atom or a methyl group, and m is preferably 1 or 2. R¹³ is preferably a methyl group or an ethyl group.

Examples of the group represented by the formula (Y):

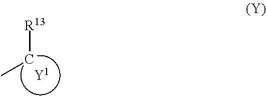

include the followings:

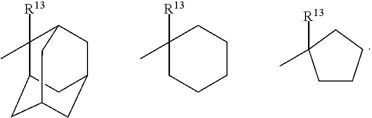

Examples of the group represented by the formula (II) include the group represented by the formula (II-1):

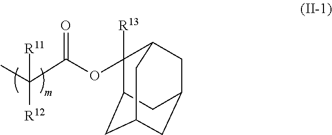

wherein R¹¹, R¹², m and R¹³ are the same as defined above.

Examples of COMPOUND (I) wherein X¹, X², X³, X⁴, X⁵, X⁶, X⁷, X⁸, X⁹ and X¹⁰ are hydrogen atoms include the compounds represented by the formulae (5-1) and (5-2):

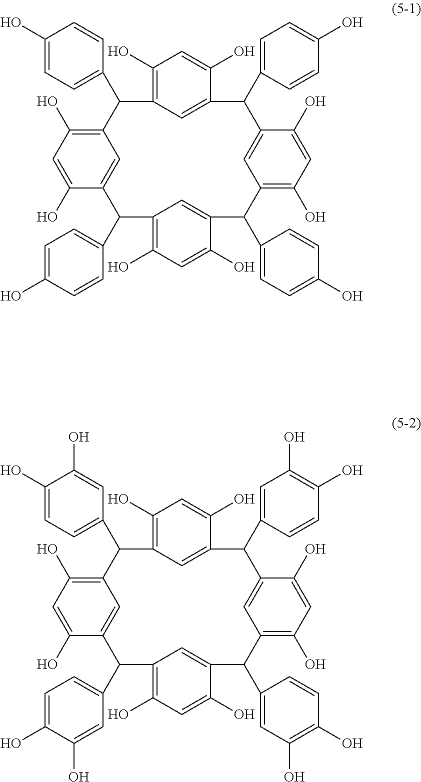

COMPOUND (I) wherein one or more selected from the groups consisting of X¹, X², X³, X⁴, X³, X⁶, X⁷, X⁸, X⁹ and X¹⁰ are the groups represented by the formula (II) can be produced by reacting COMPOUND (II) wherein X¹, X², X³, X⁴, X⁵, X⁶, X⁷, X⁸, X⁹ and X¹⁰ are hydrogen atoms with a compound represented by the formula (II'):

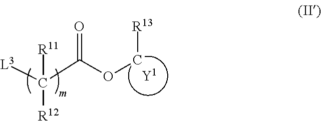

wherein R¹¹, R¹², m, R¹³ and ring Y¹ are the same as defined above and L³ represents a halogen atom, a methanesulfonyloxy group or a toluenesulfonyloxy group. Examples of the halogen atom include a chlorine atom, a bromine atom and an iodine atom. COMPOUND (I) wherein one or more selected from the groups consisting of X¹, X², X³, X⁴, X³, X⁶, X⁷, X⁸, X⁹ and X¹⁰ are the groups represented by the formula (II) can be further reacted with the compound represented by the formula (II′). The above-mentioned reaction is usually conducted in an inert solvent such as toluene, tetrahydrofuran, N,N-dimethylformamide and dimethylsulfoxide at −30 to 200° C., preferably at 0 to 150° C. The amount of the compound represented by the formula (II′) is usually 1 to (n−1) moles relative to n moles of the hydroxyl groups in COMPOUND (I) wherein X¹, X², X³, X⁴, X⁵, X⁶, X⁷, X⁸, X⁹ and X¹⁰ are hydrogen atoms, and preferably 1 to (n−2) moles. The reaction can be preferably carried out in the presence of a base and examples of the base include organic bases such as triethylamine, pyridine, sodium methoxide, sodium ethoxide and potassium tert-butoxide, inorganic bases such as sodium hydride, potassium carbonate and sodium hydroxide and a mixture thereof. The amount of the base is usually 1 to 6 moles relative to 1 moles of the compound represented by the formula (II′), and preferably 1 to 4 moles. The reaction may be conducted in the presence of a phase transfer catalyst such as tetrabutylammonium bromide. After completion of the reaction, COMPOUND (I) wherein one or more selected from the groups consisting of X¹, X², X³, X⁴, X⁵, X⁶, X⁷, X⁸, X⁹ and X¹⁰ are the groups represented by the formula (II) can be isolated by a conventional isolating method, and a mixture of two or more COMPOUND (I) wherein one or more selected from the groups consisting of X¹, X², X³, X⁴, X⁵, X⁶, X⁷, X⁸, X⁹ and X¹⁰ are the groups represented by the formula (II) is usually isolated, and the mixture may be further purified by a conventional purification means such as column chromatography, recrystallization and distillation.

The molecular weight of COMPOUND (I) is usually 300 to 5,000, preferably 400 to 4,500 and more preferably 500 to 4,000.

Examples of COMPOUND (I) include

COMPOUND (I) wherein X¹, X², X³, X⁴, X⁵, X⁶, X⁷, X⁸, X⁹ and X¹⁰ are hydrogen atoms,

COMPOUND (I) wherein any one of X¹, X², X³, X⁴, X⁵, X⁶, X⁷ and X⁸ is the group represented by the formula (II) and the other seven groups are hydrogen atoms and R¹ to R⁴ are C1-C6 alkyl groups,

COMPOUND (I) wherein any one of X¹, X², X³, X⁴, X⁵, X⁶, X⁷ and X⁸ are the group represented by the formula (II) and the other seven groups are hydrogen atoms and R¹ to R⁴ are methyl groups,

COMPOUND (I) wherein any one of X¹, X², X³, X⁴, X⁵, X⁶, X⁷ and X⁸ are the group represented by the formula (II) and the other seven groups are hydrogen atoms and R¹ to R⁴ are ethyl groups,

COMPOUND (I) wherein any two of X¹, X², X³, X⁴, X⁵, X⁶, X⁷ and X⁸ are the groups represented by the formula (II) and the other six groups are hydrogen atoms and R¹ to R⁴ are C1-C6 alkyl groups,

COMPOUND (I) wherein any two of X¹, X², X³, X⁴, X⁵, X⁶, X⁷ and X⁸ are the groups represented by the formula (II) and the other six groups are hydrogen atoms and R¹ to R⁴ are methyl groups,

COMPOUND (I) wherein any two of X¹, X², X³, X⁴, X⁵, X⁶, X⁷ and X⁸ are the groups represented by the formula (II) and the other six groups are hydrogen atoms and R¹ to R⁴ are ethyl groups,

COMPOUND (I) wherein any three of X′, X², X³, X⁴, X⁵, X⁶, X⁷ and X⁸ are the groups represented by the formula (II) and the other five groups are hydrogen atoms and R¹ to R⁴ are C1-C6 alkyl groups,

COMPOUND (I) wherein any three of X¹, X², X³, X⁴, X⁵, X⁶, X⁷ and X⁸ are the groups represented by the formula (II) and the other five groups are hydrogen atoms and R¹ to R⁴ are methyl groups,

COMPOUND (I) wherein any three of X¹, X², X³, X⁴, X⁵, X⁶, X⁷ and X⁸ are the groups represented by the formula (II) and the other five groups are hydrogen atoms and R¹ to R⁴ are ethyl groups,

COMPOUND (I) wherein any four of X¹, X², X³, X⁴, X⁵, X⁶, X⁷ and X⁸ are the groups represented by the formula (II) and the other four groups are hydrogen atoms and R¹ to R⁴ are C1-C6 alkyl groups,

COMPOUND (I) wherein any four of X¹, X², X³, X⁴, X⁵, X⁶, X⁷ and X⁸ are the groups represented by the formula (II) and the other four groups are hydrogen atoms and R¹ to R⁴ are methyl groups,

COMPOUND (I) wherein any four of X¹, X², X³, X⁴, X⁵, X⁶, X⁷ and X⁸ are the groups represented by the formula (II) and the other four groups are hydrogen atoms and R¹ to R⁴ are ethyl groups,

COMPOUND (I) wherein any five of X¹, X², X³, X⁴, X⁵, X⁶, X⁷ and X⁸ are the groups represented by the formula (II) and the other three groups are hydrogen atoms and R¹ to R⁴ are C1-C6 alkyl groups,

COMPOUND (I) wherein any five of X¹, X², X³, X⁴, X⁵, X⁶, X⁷ and X⁸ are the groups represented by the formula (II) and the other three groups are hydrogen atoms and R¹ to R⁴ are methyl groups,

COMPOUND (I) wherein any five of X¹, X², X³, X⁴, X⁵, X⁶, X⁷ and X⁸ are the groups represented by the formula (II) and the other three groups are hydrogen atoms and R¹ to R⁴ are ethyl groups,

COMPOUND (I) wherein any one of X¹, X², X³, X⁴, X⁵, X⁶, X⁷ and X⁸ is the group represented by the formula (II) and the other seven groups are hydrogen atoms and R¹ to R⁴ are phenyl groups,

COMPOUND (I) wherein any two of X¹, X², X³, X⁴, X⁵, X⁶, X⁷ and X⁸ are the groups represented by the formula (II) and the other six groups are hydrogen atoms and R¹ to R⁴ are phenyl groups,

COMPOUND (I) wherein any three of X¹, X², X³, X⁴, X⁵, X⁶, X⁷ and X⁸ are the groups represented by the formula (II) and the other five groups are hydrogen atoms and R¹ to R⁴ are phenyl groups,

COMPOUND (I) wherein any four of X¹, X², X³, X⁴, X⁵, X⁶, X⁷ and X⁸ are the groups represented by the formula (II) and the other four groups are hydrogen atoms and R¹ to R⁴ are phenyl groups,

COMPOUND (I) wherein any five of X¹, X², X³, X⁴, X⁵, X⁶, X⁷ and X⁸ are the groups represented by the formula (II) and the other three groups are hydrogen atoms and R¹ to R⁴ are phenyl groups,

COMPOUND (I) wherein R¹ to R⁴ are phenyl groups having the group represented by —OX¹⁰, any one of X¹, X², X³, X⁴, X⁵, X⁶, X⁷, X⁸ and X¹⁰ is the group represented by the formula (II) and the other groups are hydrogen atoms,

COMPOUND (I) wherein R¹ to R⁴ are phenyl groups having the group represented by —OX¹⁰, any two of X¹, X², X³, X⁴, X⁵, X⁶, X⁷, X⁸ and X¹⁰ are the groups represented by the formula (II) and the other groups are hydrogen atoms,

COMPOUND (I) wherein R¹ to R⁴ are phenyl groups having the group represented by —OX¹⁰, any three of X¹, X², X³, X⁴, X⁵, X⁶, X⁷, X⁸ and X¹⁰ are the groups represented by the formula (II) and the other groups are hydrogen atoms,

COMPOUND (I) wherein R¹ to R⁴ are phenyl groups having the group represented by —OX¹⁰, any four of X¹, X², X³, X⁴, X⁵, X⁶, X⁷, X⁸ and X¹⁰ are the groups represented by the formula (II) and the other groups are hydrogen atoms,

COMPOUND (I) wherein R¹ to R⁴ are phenyl groups having the group represented by —OX¹⁰, any five of X¹, X², X³, X⁴, X⁵, X⁶, X⁷, X⁸ and X¹⁰ are the groups represented by the formula (II) and the other groups are hydrogen atoms,

COMPOUND (I) wherein R¹ to R⁴ are phenyl groups having the group represented by —OX¹⁰, any six of X¹, X², X³, X⁴, X⁵, X⁶, X⁷, X⁸ and X¹⁰ are the groups represented by the formula (II) and the other groups are hydrogen atoms,

COMPOUND (I) wherein R¹ to R⁴ are phenyl groups having the group represented by —OX¹⁰, any seven of X¹, X², X³, X⁴, X⁵, X⁶, X⁷, X⁸ and X¹⁰ are the groups represented by the formula (II) and the other groups are hydrogen atoms,

COMPOUND (I) wherein R¹ to R⁴ are phenyl groups having the group represented by —OX¹⁰, any eight of X¹, X², X³, X⁴, X⁵, X⁶, X⁷, X⁸ and X¹⁰ are the groups represented by the formula (II) and the other groups are hydrogen atoms,

COMPOUND (I) wherein R¹ to R⁴ are phenyl groups having the two groups represented by —OX¹⁰, any one of X¹, X², X³, X⁴, X⁵, X⁶, X⁷, X⁸ and X¹⁰ is the group represented by the formula (II) and the other groups are hydrogen atoms,

COMPOUND (I) wherein R¹ to R⁴ are phenyl groups having the two groups represented by —OX¹⁰, any two of X¹, X², X³, X⁴, X⁵, X⁶, X⁷, X⁸ and X¹⁰ are the groups represented by the formula (II) and the other groups are hydrogen atoms,

COMPOUND (I) wherein R¹ to R⁴ are phenyl groups having the two groups represented by —OX¹⁰, any three of X¹, X², X³, X⁴, X⁵, X⁶, X⁷, X⁸ and X¹⁰ are the groups represented by the formula (II) and the other groups are hydrogen atoms,

COMPOUND (I) wherein R¹ to R⁴ are phenyl groups having the two groups represented by —OX¹⁰, any four of X¹, X², X³, X⁴, X⁵, X⁶, X⁷, X⁸ and X¹⁰ are the groups represented by the formula (II) and the other groups are hydrogen atoms,

COMPOUND (I) wherein R¹ to R⁴ are phenyl groups having the two groups represented by —OX¹⁰, any five of X¹, X², X³, X⁴, X⁵, X⁶, X⁷, X⁸ and X¹⁰ are the groups represented by the formula (II) and the other groups are hydrogen atoms,

COMPOUND (I) wherein R¹ to R⁴ are phenyl groups having the two groups represented by —OX¹⁰, any six of X¹, X², X³, X⁴, X⁵, X⁶, X⁷, X⁸ and X¹⁰ are the groups represented by the formula (II) and the other groups are hydrogen atoms,

COMPOUND (I) wherein R¹ to R⁴ are phenyl groups having the two groups represented by —OX¹⁰, any seven of X¹, X², X³, X⁴, X⁵, X⁶, X⁷, X⁸ and X¹⁰ are the groups represented by the formula (II) and the other groups are hydrogen atoms, and

COMPOUND (I) wherein R¹ to R⁴ are phenyl groups having the two groups represented by —OX¹⁰, any eight of X¹, X², X³, X⁴, X⁵, X⁶, X⁷, X⁸ and X¹⁰ are the groups represented by the formula (II) and the other groups are hydrogen atoms.

The photoresist composition preferably contains COMPOUND (I) wherein at least one selected from the group consisting of X¹, X², X³, X⁴, X⁵, X⁶, X⁷ and X⁸ is the group represented by the formula (II).

The photoresist composition of the present invention preferably contains two or more kinds of COMPOUND (I). The photoresist composition of the present invention preferably contains COMPOUND (I) wherein one or more selected from the groups consisting of X¹, X², X³, X⁴, X⁵, X⁶, X⁷, X⁸, X⁹ and X¹⁰ are the groups represented by the formula (II), and more preferably contains COMPOUND (I) wherein three or more selected from the groups consisting of X¹, X², X³, X⁴, X⁵, X⁶, X⁷, X⁸, X⁹ and X¹⁰ are the groups represented by the formula (II).

Examples of the photoresist composition of the present invention include a photoresist composition containing at least one selected from the group consisting of COMPOUND (I) wherein any one of X¹, X², X³, X⁴, X⁵, X⁶, X⁷ and X⁸ is the group represented by the formula (II) and the other seven groups are hydrogen atoms and R¹ to R⁴ are C1-C6 alkyl groups, COMPOUND (I) wherein any two of X¹, X², X³, X⁴, X⁵, X⁶, X⁷ and X⁸ are the groups represented by the formula (II) and the other six groups are hydrogen atoms and R¹ to R⁴ are C1-C6 alkyl groups, COMPOUND (I) wherein any three of X¹, X², X³, X⁴, X⁵, X⁶, X⁷ and X⁸ are the groups represented by the formula (II) and the other five groups are hydrogen atoms and R¹ to R⁴ are C1-C6 alkyl groups, COMPOUND (I) wherein any four of X¹, X², X³, X⁴, X⁵, X⁶, X⁷ and X⁸ are the groups represented by the formula (II) and the other four groups are hydrogen atoms and R¹ to R⁴ are C1-C6 alkyl groups, and COMPOUND (I) wherein any five of X¹, X², X³, X⁴, X⁵, X⁶, X⁷ and X⁸ are the groups represented by the formula (II) and the other three groups are hydrogen atoms and R¹ to R⁴ are C1-C6 alkyl groups.

Preferable examples of the photoresist composition of the present invention include a photoresist composition containing at least one selected from the group consisting of COMPOUND (I) wherein any one of X¹, X², X³, X⁴, X⁵, X⁶, X⁷ and X⁸ are the group represented by the formula (II) and the other seven groups are hydrogen atoms and R¹ to R⁴ are methyl groups, COMPOUND (I) wherein any two of X¹, X², X³, X⁴, X⁵, X⁶, X⁷ and X⁸ are the groups represented by the formula (II) and the other six groups are hydrogen atoms and R¹ to R⁴ are methyl groups, COMPOUND (I) wherein any three of X¹, X², X³, X⁴, X⁵, X⁶, X⁷ and X⁸ are the groups represented by the formula (II) and the other five groups are hydrogen atoms and R¹ to R⁴ are methyl groups, COMPOUND (I) wherein any four of X¹, X², X³, X⁴, X⁵, X⁶, X⁷ and X⁸ are the groups represented by the formula (II) and the other four groups are hydrogen atoms and R¹ to R⁴ are methyl groups, and COMPOUND (I) wherein any five of X¹, X², X³, X⁴, X⁵, X⁶, X⁷ and X⁸ are the groups represented by the formula (II) and the other three groups are hydrogen atoms and R¹ to R⁴ are methyl groups,

a photoresist composition containing at least one selected from the group consisting of COMPOUND (I) wherein any one of X¹, X², X³, X⁴, X⁵, X⁶, X⁷ and X⁸ are the group represented by the formula (II) and the other seven groups are hydrogen atoms and R¹ to R⁴ are ethyl groups, COMPOUND (I) wherein any two of X¹, X², X³, X⁴, X⁵, X⁶, X⁷ and X⁸ are the groups represented by the formula (II) and the other six groups are hydrogen atoms and R¹ to R⁴ are ethyl groups, COMPOUND (I) wherein any three of X¹, X², X³, X⁴, X⁵, X⁶, X⁷ and X⁸ are the groups represented by the formula (II) and the other five groups are hydrogen atoms and R¹ to R⁴ are ethyl groups, COMPOUND (I) wherein any four of X¹, X², X³, X⁴, X⁵, X⁶, X⁷ and X⁸ are the groups represented by the formula (II) and the other four groups are hydrogen atoms and R¹ to R⁴ are ethyl groups, and COMPOUND (I) wherein any five of X¹, X², X³, X⁴, X⁵, X⁶, X⁷ and X⁸ are the groups represented by the formula (II) and the other three groups are hydrogen atoms and R¹ to R⁴ are ethyl groups,

a photoresist composition containing at least one selected from the group consisting of COMPOUND (I) wherein any one of X¹, X², X³, X⁴, X⁵, X⁶, X⁷ and X⁸ is the group represented by the formula (II) and the other seven groups are hydrogen atoms and R¹ to R⁴ are phenyl groups, COMPOUND (I) wherein any two of X¹, X², X³, X⁴, X⁵, X⁶, X⁷ and X⁸ are the groups represented by the formula (II) and the other six groups are hydrogen atoms and R¹ to R⁴ are phenyl groups, COMPOUND (I) wherein any three of X¹, X², X³, X⁴, X⁵, X⁶, X⁷ and X⁸ are the groups represented by the formula (II) and the other five groups are hydrogen atoms and R¹ to R⁴ are phenyl groups, COMPOUND (I) wherein any four of X¹, X², X³, X⁴, X⁵, X⁶, X⁷ and X⁸ are the groups represented by the formula (II) and the other four groups are hydrogen atoms and R¹ to R⁴ are phenyl groups, and COMPOUND (I) wherein any five of X¹, X², X³, X⁴, X⁵, X⁶, X⁷ and X⁸ are the groups represented by the formula (II) and the other three groups are hydrogen atoms and R¹ to R⁴ are phenyl groups, a photoresist composition containing at least one selected from the group consisting of COMPOUND (I) wherein R¹ to R⁴ are phenyl groups having the group represented by —OX¹⁰, any one of X¹, X², X³, X⁴, X⁵, X⁶, X⁷, X⁸ and X¹⁰ is the group represented by the formula (II) and the other groups are hydrogen atoms, COMPOUND (I) wherein R¹ to R⁴ are phenyl groups having the group represented by —OX¹⁰, any two of X¹, X², X³, X⁴, X⁵, X⁶, X⁷, X⁸ and X¹⁰ are the groups represented by the formula (II) and the other groups are hydrogen atoms, COMPOUND (I) wherein R¹ to R⁴ are phenyl groups having the group represented by —OX¹⁰, any three of X¹, X², X³, X⁴, X⁵, X⁶, X⁷, X⁸ and X¹⁰ are the groups represented by the formula (II) and the other groups are hydrogen atoms, COMPOUND (I) wherein R¹ to R⁴ are phenyl groups having the group represented by —OX¹⁰, any four of X¹, X², X³, X⁴, X⁵, X⁶, X⁷, X⁸ and X¹⁰ are the groups represented by the formula (II) and the other groups are hydrogen atoms, COMPOUND (I) wherein R¹ to R⁴ are phenyl groups having the group represented by —OX¹⁰, any five of X¹, X², X³, X⁴, X⁵, X⁶, X⁷, X⁸ and X¹⁰ are the groups represented by the formula (II) and the other groups are hydrogen atoms, COMPOUND (I) wherein R¹ to R⁴ are phenyl groups having the group represented by —OX¹⁰, any six of X¹, X², X³, X⁴, X⁵, X⁶, X⁷, X⁸ and X¹⁰ are the groups represented by the formula (II) and the other groups are hydrogen atoms, COMPOUND (I) wherein R¹ to R⁴ are phenyl groups having the group represented by —OX¹⁰, any seven of X¹, X², X³, X⁴, X⁵, X⁶, X⁷, X⁸ and X¹⁰ are the groups represented by the formula (II) and the other groups are hydrogen atoms, and COMPOUND (I) wherein R¹ to R⁴ are phenyl groups having the group represented by —OX¹⁰, any eight of X¹, X², X³, X⁴, X⁵, X⁶, X⁷, X⁸ and X¹⁰ are the groups represented by the formula (II) and the other groups are hydrogen atoms, and

a photoresist composition containing at least one selected from the group consisting of COMPOUND (I) wherein R¹ to R⁴ are phenyl groups having the two groups represented by —OX¹⁰, any one of X¹, X², X³, X⁴, X⁵, X⁶, X⁷ and X⁸ and X¹⁰ is the group represented by the formula (II) and the other groups are hydrogen atoms, COMPOUND (I) wherein R¹ to R⁴ are phenyl groups having the two groups represented by —OX¹⁰, any two of X¹, X², X³, X⁴, X⁵, X⁶, X⁷ and X⁸ are the groups represented by the formula (II) and the other groups are hydrogen atoms, COMPOUND (I) wherein R¹ to R⁴ are phenyl groups having the two groups represented by —OX¹⁰, any three of X¹, X², X³, X⁴, X⁵, X⁶, X⁷, X⁸ and X¹⁰ are the groups represented by the formula (II) and the other groups are hydrogen atoms, COMPOUND (I) wherein R¹ to R⁴ are phenyl groups having the two groups represented by —OX¹⁰, any four of X¹, X², X³, X⁴, X⁵, X⁶, X⁷ and X⁸ and X¹⁰ are the groups represented by the formula (II) and the other groups are hydrogen atoms, COMPOUND (I) wherein R¹ to R⁴ are phenyl groups having the two groups represented by —OX¹⁰, any five of X², X³, X⁴, X⁵, X⁶, X⁷, X⁸ and X¹⁰ are the groups represented by the formula (II) and the other groups are hydrogen atoms, COMPOUND (I) wherein R¹ to R⁴ are phenyl groups having the two groups represented by —OX¹⁰, any six of X¹, X², X³, X⁴, X⁵, X⁶, X⁷, X⁸ and X¹⁰ are the groups represented by the formula (II) and the other groups are hydrogen atoms, COMPOUND (I) wherein R¹ to R⁴ are phenyl groups having the two groups represented by —OX¹⁰, any seven of X¹, X², X³, X⁴, X⁵, X⁶, X⁷, X⁸ and X¹⁰ are the groups represented by the formula (II) and the other groups are hydrogen atoms, and COMPOUND (I) wherein R¹ to R⁴ are phenyl groups having the two groups represented by —OX¹⁰, any eight of X¹, X², X³, X⁴, X⁵, X⁶, X⁷, X⁸ and X¹⁰ are the groups represented by the formula (II) and the other groups are hydrogen atoms.

The content of COMPOUND (I) in the photoresist composition of the present invention is usually 80 to 99.9% by weight, preferably 80 to 99% by weight and more preferably 90 to 99% by weight based on 100% by weight of the solid component. In this specification, “solid component” means components other than solvent in the photoresist composition. The content can be measured according to known analytical methods.

The photoresist composition of the present invention contains the acid generator represented by the formula (B1):

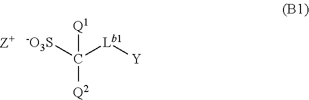

wherein Q¹ and Q² independently represent a fluorine atom or a C1-C6 perfluoroalkyl group, L^{b1} represents a single bond or a C1-C17 saturated divalent hydrocarbon group in which one or more —CH₂— can be replaced by —O— or —CO—, Y represents a C1-C18 aliphatic hydrocarbon group or a C3-C18 saturated cyclic hydrocarbon group, and the aliphatic hydrocarbon group and the saturated cyclic hydrocarbon group can have one or more substituents, and one or more —CH₂— in the aliphatic hydrocarbon group and the saturated cyclic hydrocarbon group can be replaced by —O—, —CO— or —SO₂—, and Z⁺ represents an organic cation.

Examples of the C1-C6 perfluoroalkyl group include a trifluoromethyl group, a pentafluoroethyl group, a heptafluoropropyl group, a nonafluorobutyl group, an undecafluoropentyl group and a tridecafluorohexyl group, and a trifluoromethyl group is preferable. Q¹ and Q² independently preferably represent a fluorine atom or a trifluoromethyl group, and Q¹ and Q² are more preferably fluorine atoms.

Examples of the C1-C17 saturated divalent hydrocarbon group include a C1-C17 alkanediyl group and a divalent group having an alicyclic divalent hydrocarbon group. Examples of the alkanediyl group include a linear alkanediyl group such as a methylene group, an ethylene group, a propane-1,3-diyl group, a butane-1,4-diyl group, a pentane-1,5-diyl, a hexane-1,6-diyl group, a heptane-1,7-diyl group, an octane-1,8-diyl group, a nonane-1,9-diyl group, a decane-1,10-diyl group, an undecane-1,11-diyl group, a dodecane-1,12-diyl group, a tridecane-1,13-diyl group, a tetradecane-1,14-diyl group, a pentadecane-1,15-diyl group, a hexadecane-1,16-diyl group and a heptadecane-1,17-diyl group, a branched chain alkanediyl group formed by replacing one or more hydrogen atom of the above-mentioned linear alkanediyl group by a C1-C4 alkyl group, and a divalent group having an alicyclic divalent hydrocarbon group such as the following groups represented by the formulae (X¹-A) to (X¹-C):

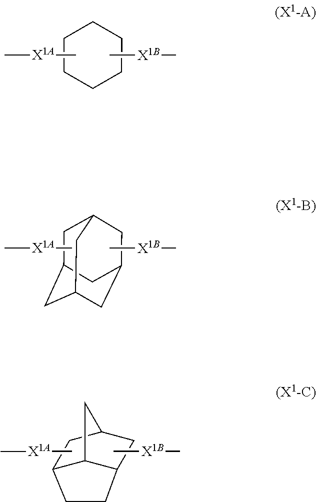

wherein X^{1A} and X^{1B} independently each represent a C1-C6 alkylene group which can have one or more substituents, with the proviso that total carbon number of the group represented by the formula (X¹-A), (X¹-B) or (X¹-C) is 1 to 17.

One or more —CH₂— in the C1-C6 alkanediyl group can be replaced by —O— or —CO—.

Examples of the C1-C17 saturated hydrocarbon group in which one or more —CH₂— are replaced by —O— or —CO— include *—CO—O-L^{b2}-, *—CO—O-L^{b4}-CO—O-L^{b3}-, *-L^{b5}-O—CO—, *—CO—O-L^{b8}-O—, and *—CO—O-L^{b10}-O-L^{b9}-CO—O—, wherein L^{b2} represents a single bond or a C1-C15 alkanediyl group, L^{b3} represents a single bond or a C1-C12 alkanediyl group, L^{b4} represents a single bond or a C1-C13 alkanediyl group, with proviso that total carbon number of L^{b3} and L^{b4} is 1 to 13, L^{b5} represents a C1-C15 alkanediyl group, L^{b6} represents a C1-C15 alkanediyl group, L^{b7} represents a C1-C15 alkanediyl group, with proviso that total carbon number of L^{b6} and L^{b7} is 1 to 16, L^{b8} represents a C1-C14 alkanediyl group, L^{b9} represents a C1-C11 alkanediyl group, L^{b10} represents a C1-C11 alkanediyl group, with proviso that total carbon number of L^{b9} and L^{b10} is 1 to 12, and * represents a binding position to —C(Q¹)(Q²)-. Among them, preferred are *—CO—O-L^{b2}-, *—CO—O-L^{b4}-CO—O-L^{b3}-, *-L^{b5}-O—CO— and *-L^{b7}-O-L^{b6}-, and more preferred are *—CO—O-L^{b2}- and *—CO—O-L^{b4}-CO—O-L^{b3}-, and much more preferred is *—CO—O-L^{b2}-, and especially preferred is *—CO—O-L^{b2}- in which L^{b2} is a single bond or —CH₂—.

Examples of *—CO—O-L^{b2}- include *—CO—O— and *—CO—O—CH₂—. Examples of *—CO—O-L^{b4}-CO—O-L^{b3}- include *—CO—O—CH₂—CO—O—, *—CO—O—(CH₂)₂—CO—O—, *—CO—O—(CH₂)₃—CO—O—, *—CO—O—(CH₂)₄—CO—O—, *—CO—O—(CH₂)₆—CO—O—, *—CO—O—(CH₂)₈—CO—O—, *—CO—O—CH₂—CH(CH₃)—CO—O— and *—CO—O—CH₂—C(CH₃)₂—CO—O—. Examples of *-L^{b5}-O—CO— include *—CH₂—O—CO—, *—(CH₂)₂—O—CO—, *—(CH₂)₃—O—CO—, *—(CH₂)₄—O—CO—, *—(CH₂)₆—O—CO— and *—(CH₂)₈—O—CO—. Examples of *-L^{b7}-O-L^{b6}- include *—CH₂—O—CH₂—. Examples of *—CO—O-L^{b8}-O— include *—CO—O—CH₂—O—, *—CO—O—(CH₂)₂—O—, *—CO—O—(CH₂)₃—O—, *—CO—O—(CH₂)₄—O— and *—CO—O—(CH₂)₆—O—. Examples of *—CO—O-L^{b10}-O-L^{b9}-CO—O— include the followings.

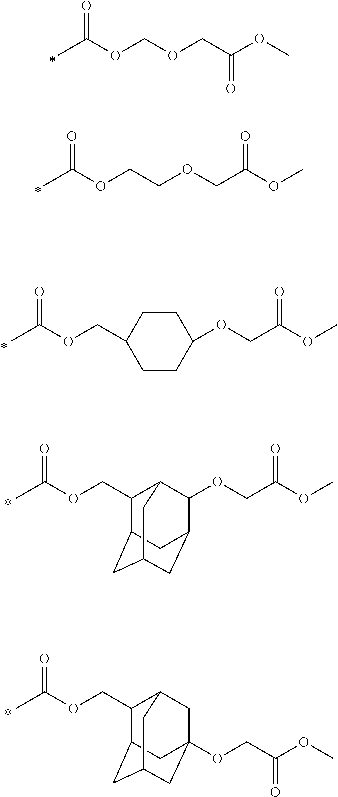

Examples of the substituent in Y include a halogen atom, a hydroxyl group, an oxo group, a glycidyloxy group, a C2-C4 acyl group, a C1-C12 alkoxy group, a C2-C7 alkoxycarbonyl group, a C01-C12 aliphatic hydrocarbon group, a C1-C12 hydroxy-containing aliphatic hydrocarbon group, a C3-C16 saturated cyclic hydrocarbon group, a C6-C18 aromatic hydrocarbon group, a C7-C21 aralkyl group and —(CH₂)ⱼ₂—O—CO—R^{b1}— in which R^{b1} represents a C1-C16 aliphatic hydrocarbon group, a C3-C16 saturated cyclic hydrocarbon group or a C6-C18 aromatic hydrocarbon group and j2 represents an integer of 0 to 4. Examples of the halogen atom include a fluorine atom, a chlorine atom, a bromine atom and an iodine atom. Examples of the acyl group include an acetyl group and a propionyl group, and examples of the alkoxy group include a methoxy group, an ethoxy group, a propoxy group, an isopropoxy group and a butoxy group. Examples of the alkoxycarbonyl group include a methoxycarbonyl group, an ethoxycarbonyl group, a propoxycarbonyl group, an isopropoxycarbonyl group and a butoxycarbonyl group. Examples of the aliphatic hydrocarbon group include the same as described above. Examples of the hydroxyl-containing aliphatic hydrocarbon group include a hydroxymethyl group. Examples of the C3-C16 saturated cyclic hydrocarbon group include the same as described above, and examples of the aromatic hydrocarbon group include a phenyl group, a naphthyl group, an anthryl group, a p-methylphenyl group, a p-tert-butylphenyl group and a p-adamantylphenyl group. Examples of the aralkyl group include a benzyl group, a phenethyl group, a phenylpropyl group, a trityl group, a naphthylmethyl group and a naphthylethyl group.

Examples of the C1-C18 aliphatic hydrocarbon group represented by Y include a methyl group, an ethyl group, a propyl group, an isopropyl group, a butyl group, an isobutyl group, a sec-butyl group, a tert-butyl group, a pentyl group, a neopentyl group, a 1-methylbutyl group, a 2-methylbutyl group, a 1,2-dimethylpropyl group, a 1-ethylpropyl group, a hexyl group, a 1-methylpentyl group, a heptyl group, an octyl group, a 2-ethylhexyl group, a nonyl group, a decyl group, an undecyl group and a dodecyl group, and a C1-C6 alkyl group is preferable. Examples of the C3-C18 saturated cyclic hydrocarbon group represented by Y include the groups represented by the formulae (Y1) to (Y26):

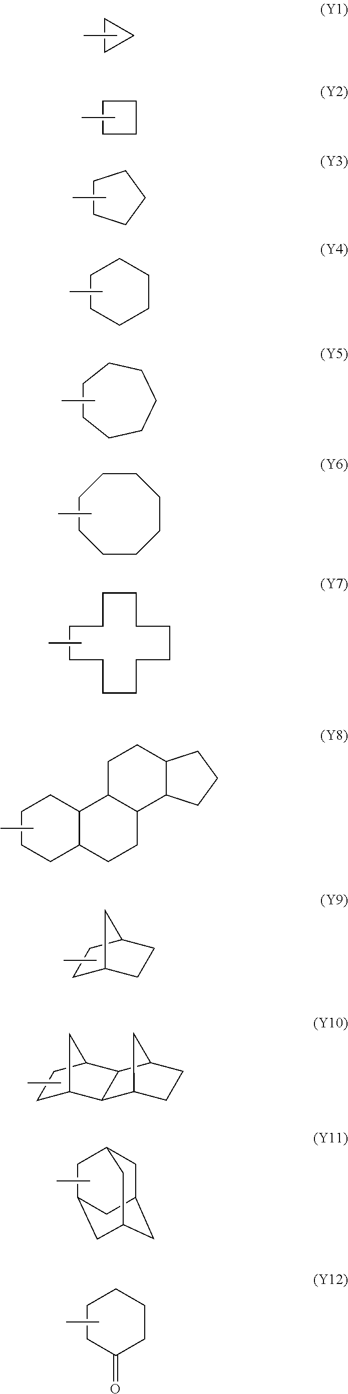

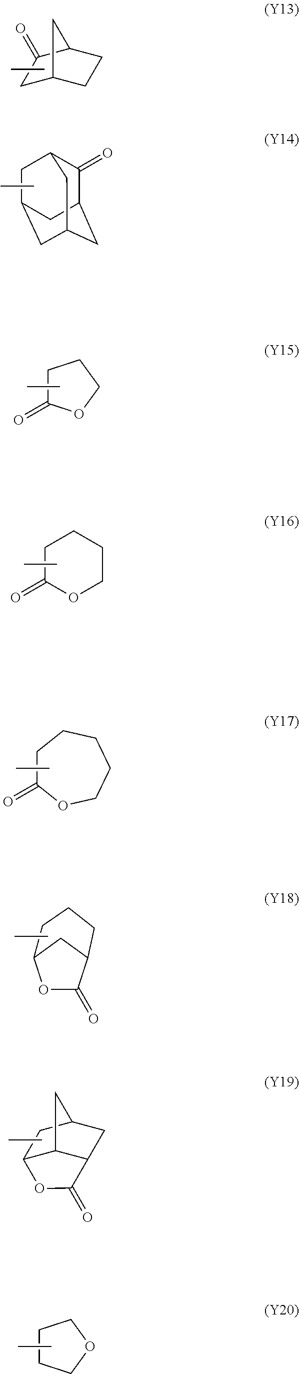

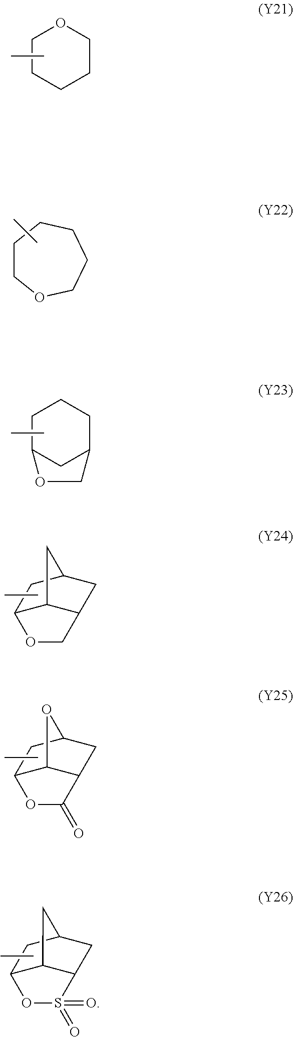

Among them, preferred are the groups represented by the formulae (Y1) to (Y19), and more preferred are the groups represented by the formulae (Y11), (Y14), (Y15) and (Y19). The groups represented by the formulae (Y11) and (Y14) are especially preferable.

Examples of Y having one or more substituents include the followings:

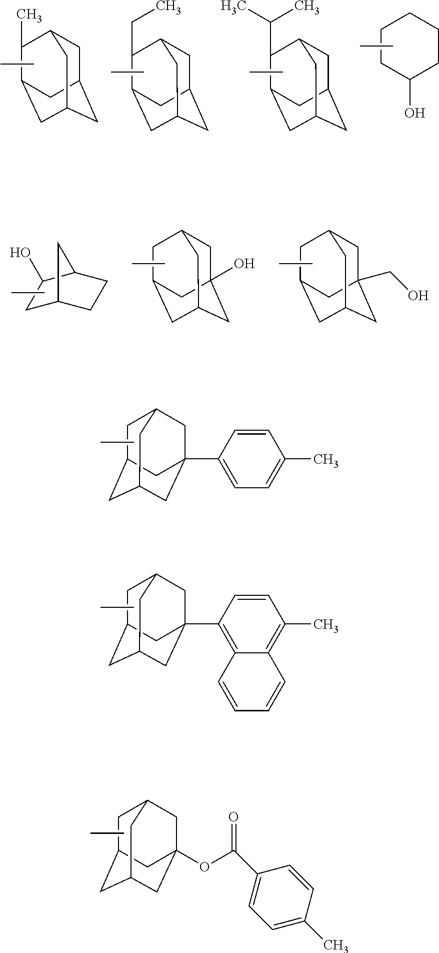

Y is preferably an adamantyl group which can have one or more substituents, and is more preferably an adamantyl group or an oxoadamantyl group.

Among the sulfonic acid anions of the acid generator represented by the formula (B1), preferred is a sulfonic acid anion in which L^{b1} is *—CO—O-L^{b2}-, and more preferred are anions represented by the formulae (b1-1-1) to (b1-1-9).

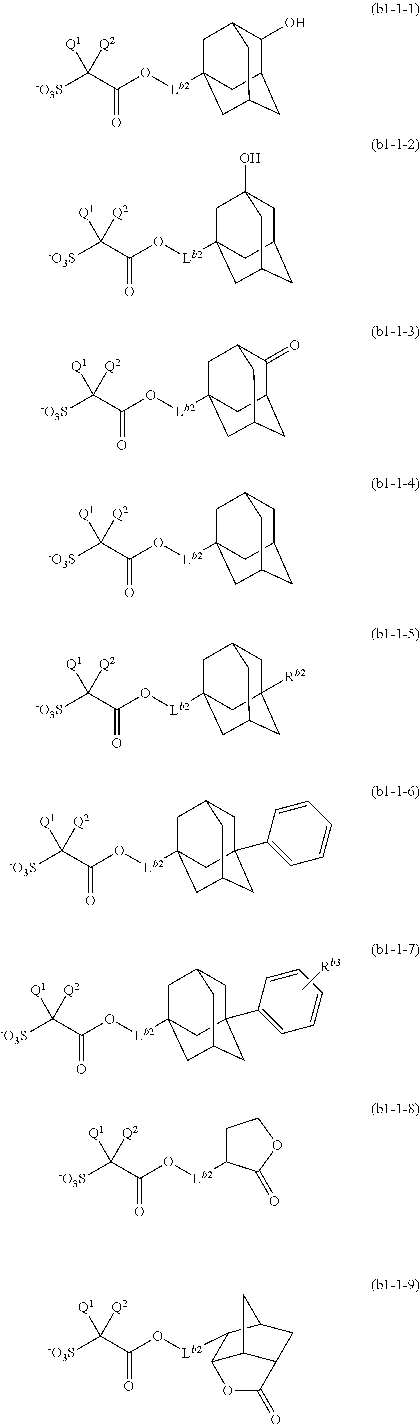

wherein Q¹, Q² and L^{b2} are the same as defined above, and R^{b2} and R^{b3} each independently represent a C1-C4 aliphatic hydrocarbon group, preferably a methyl group.

Examples of the anions of the acid generator represented by the formula (B1) include the followings.

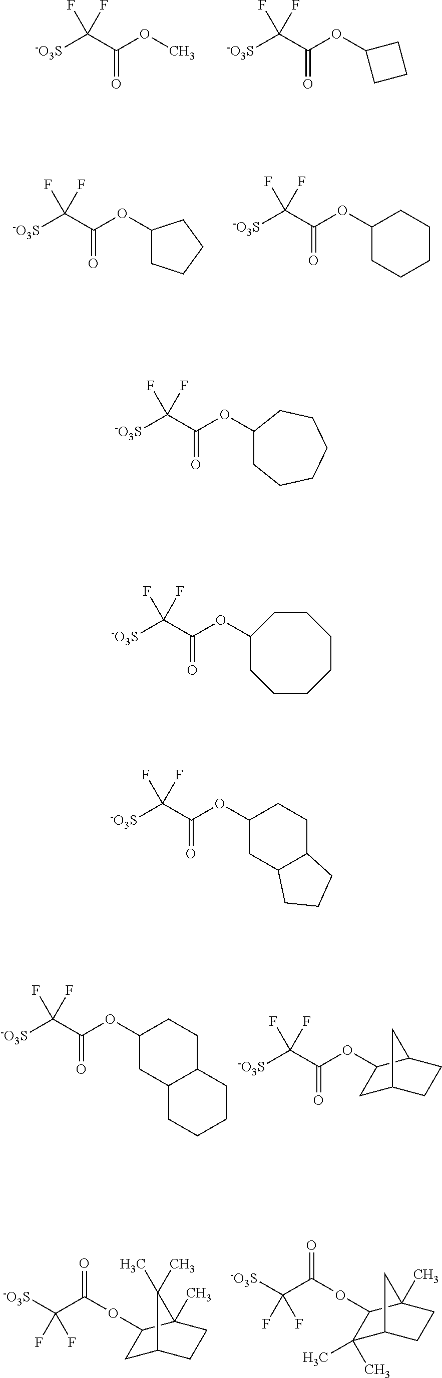

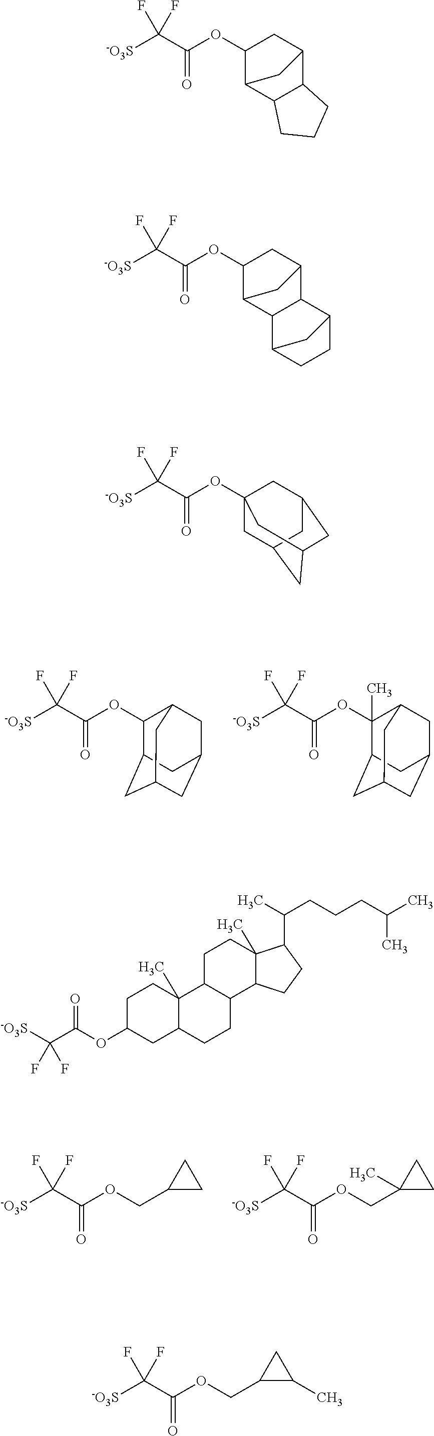

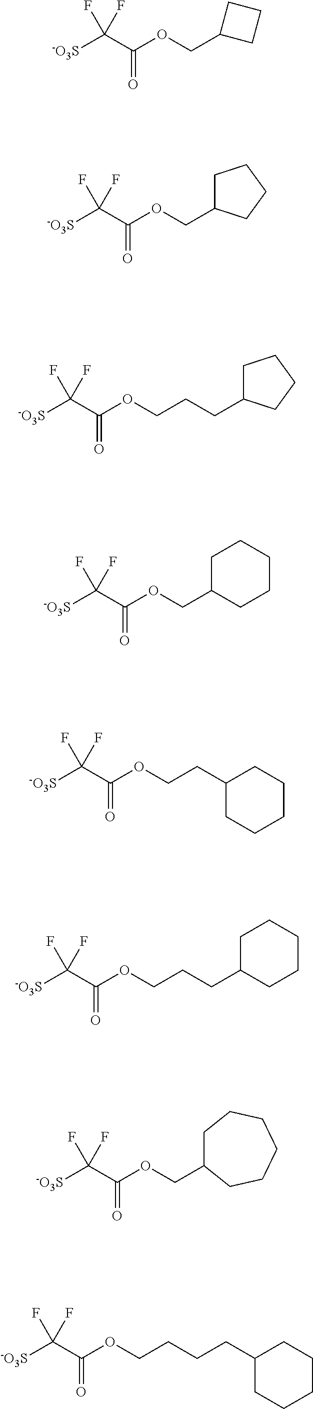

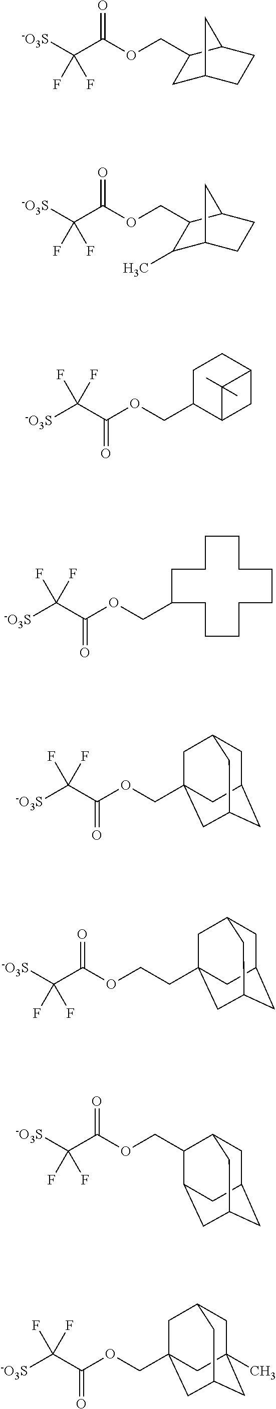

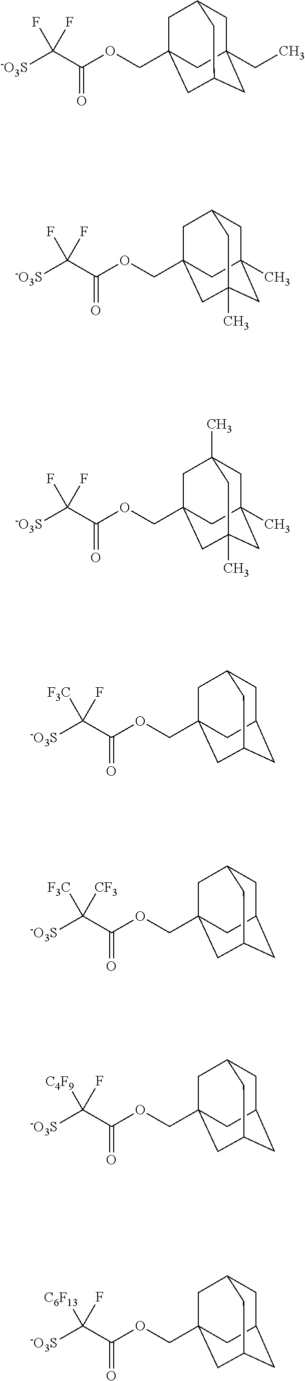

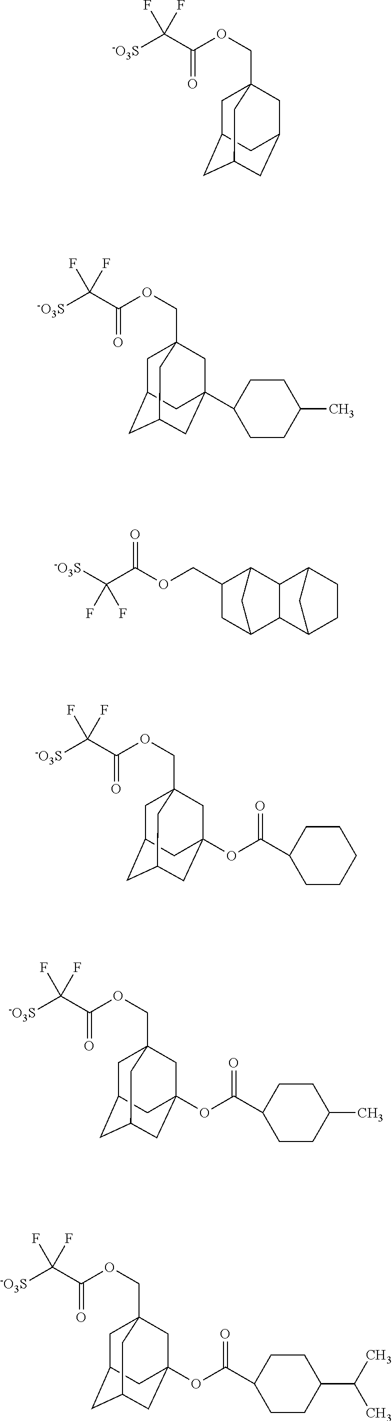

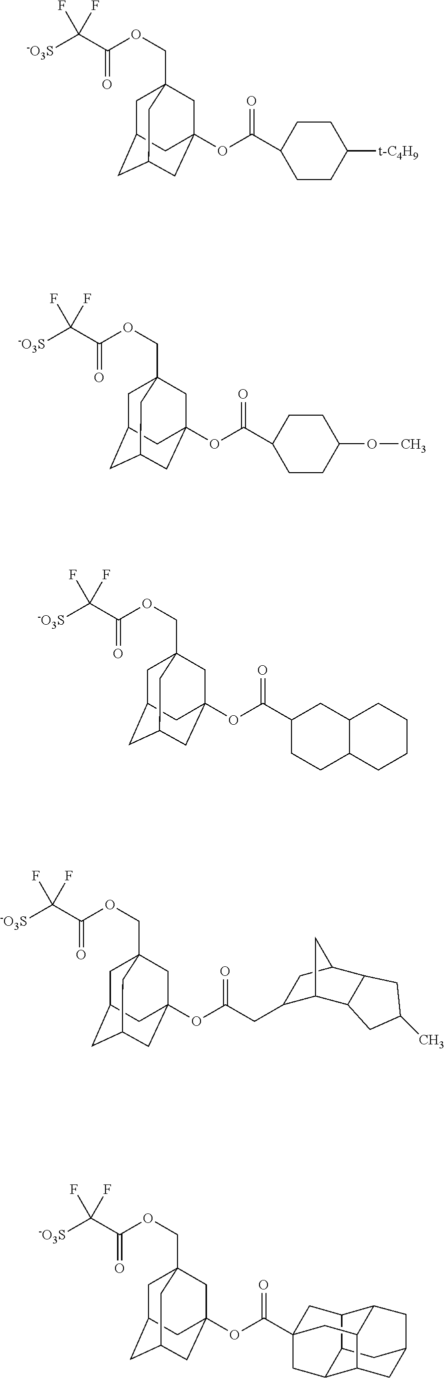

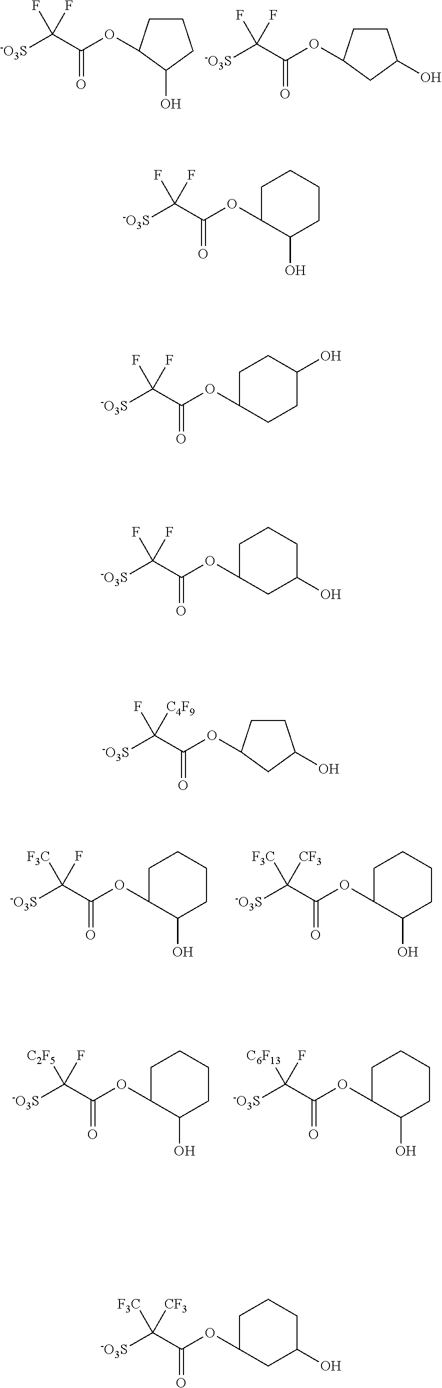

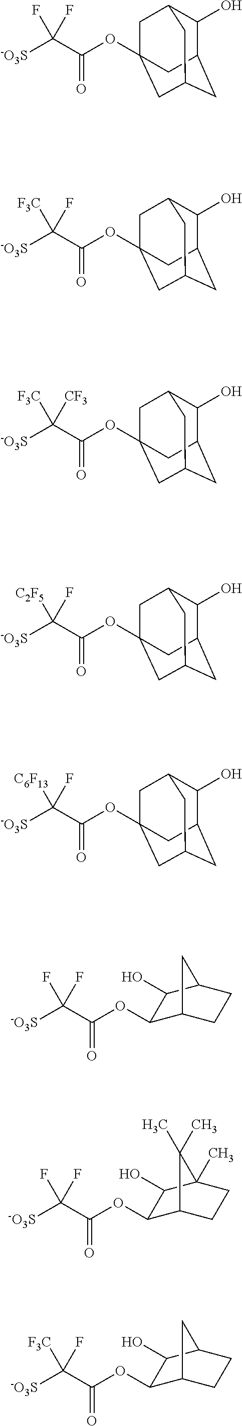

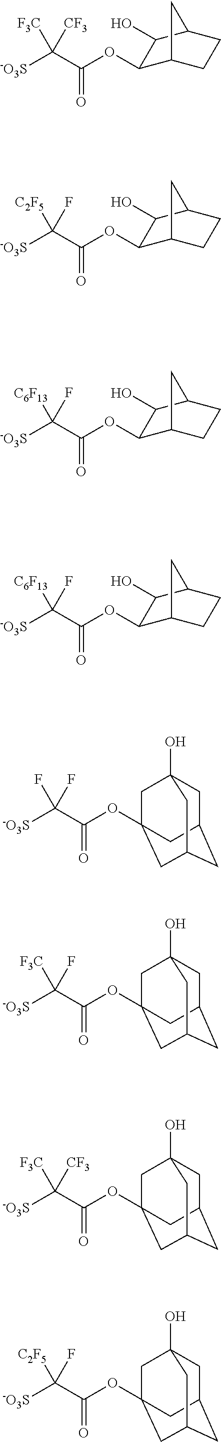

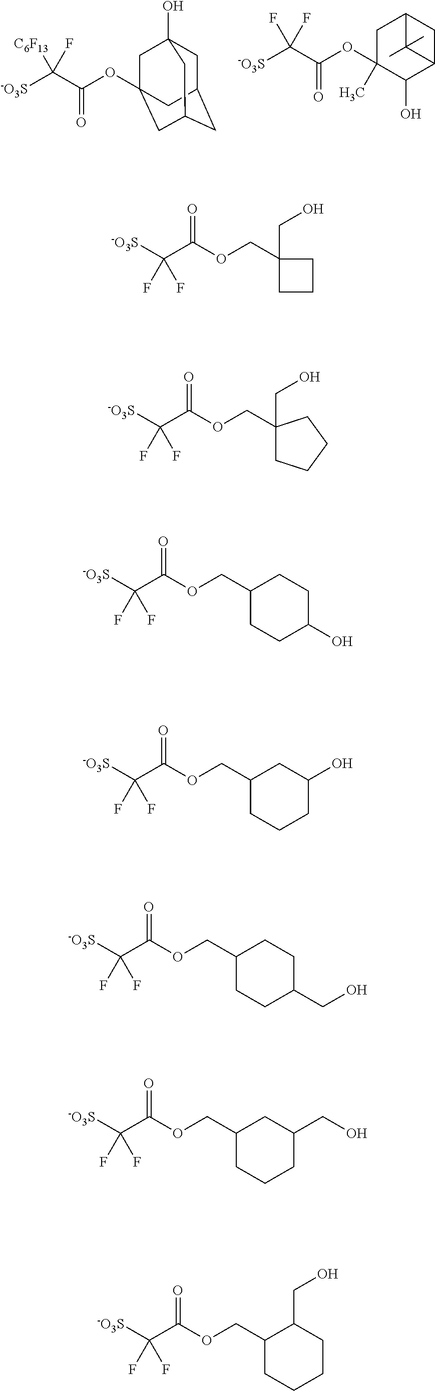

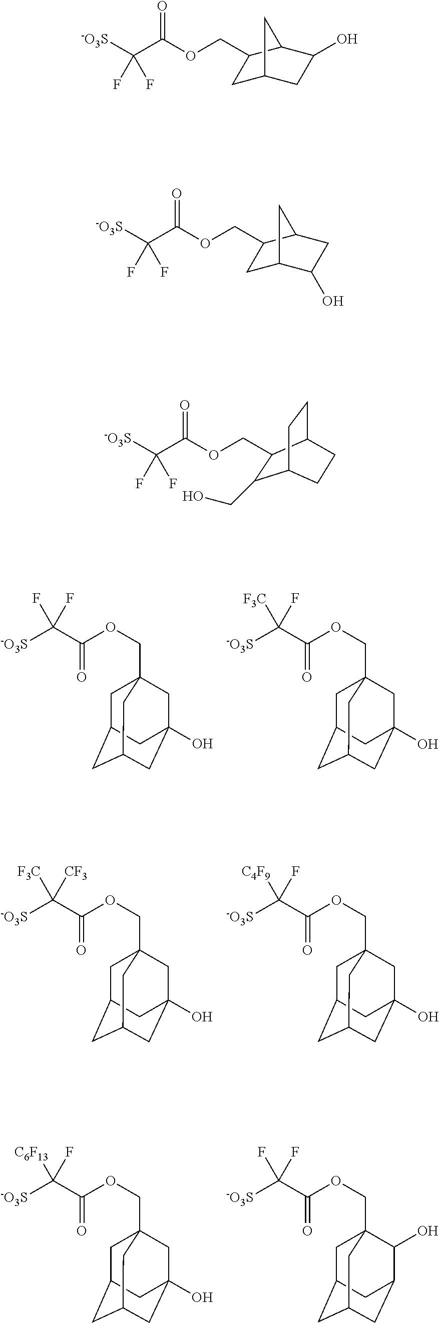

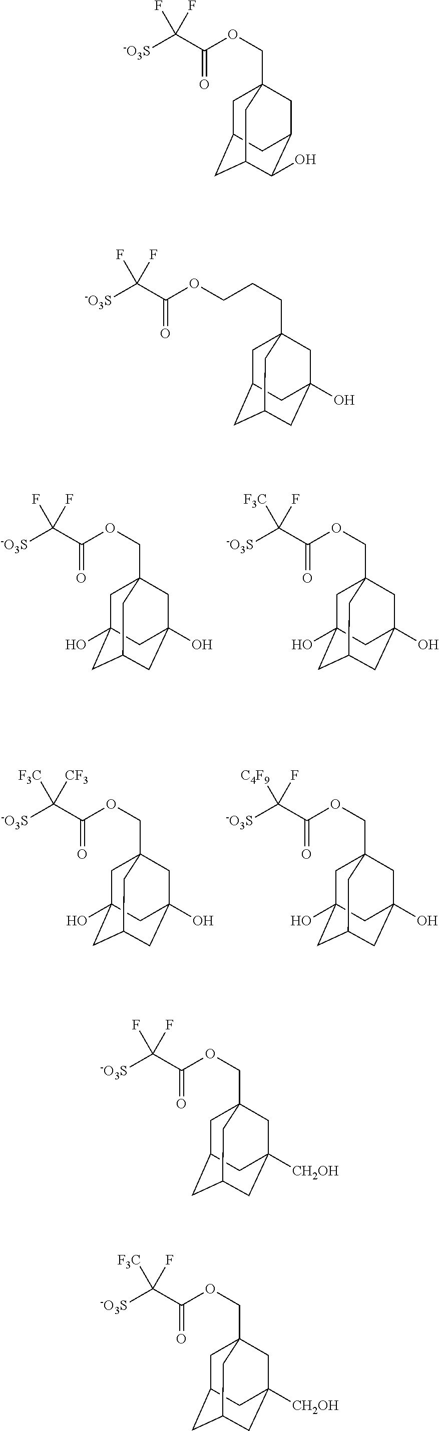

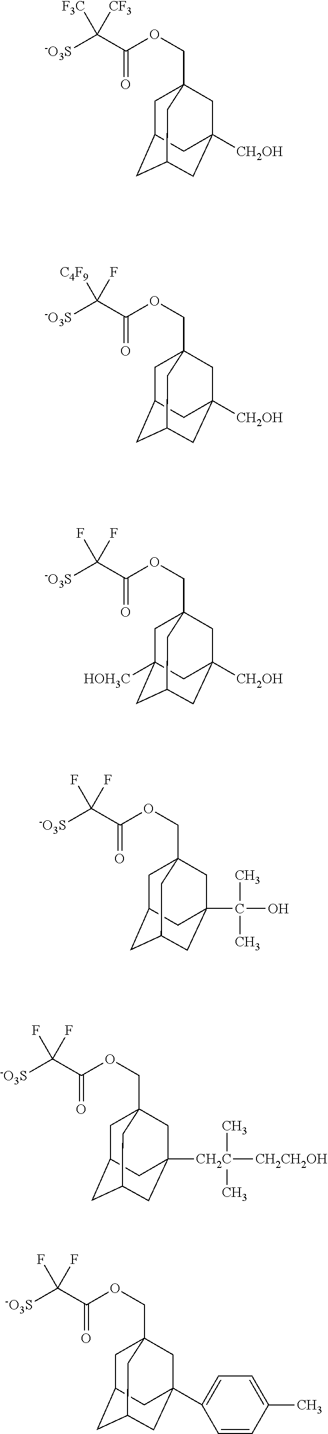

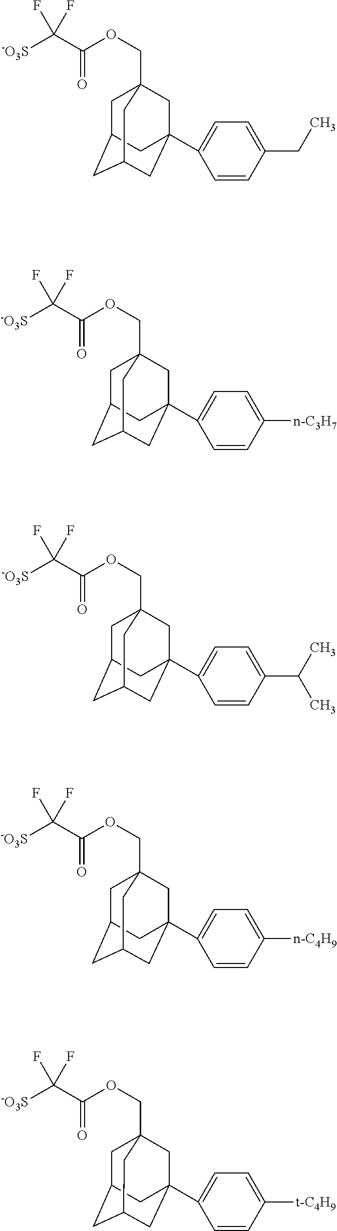

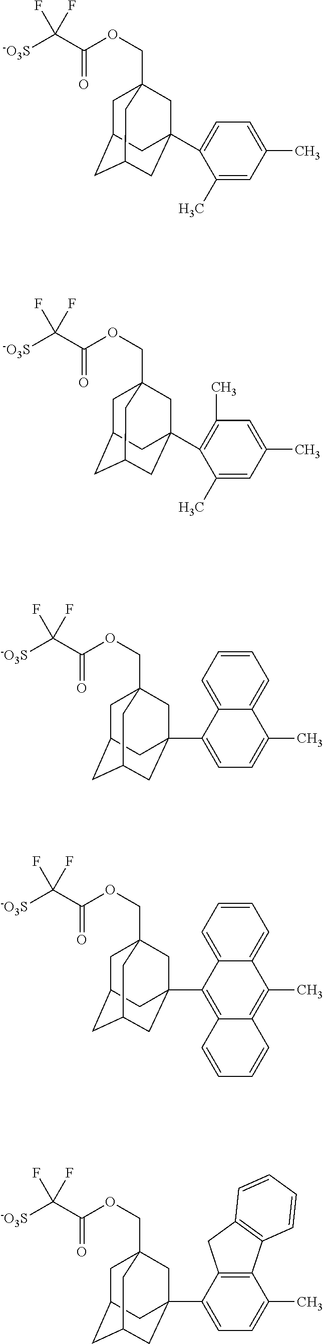

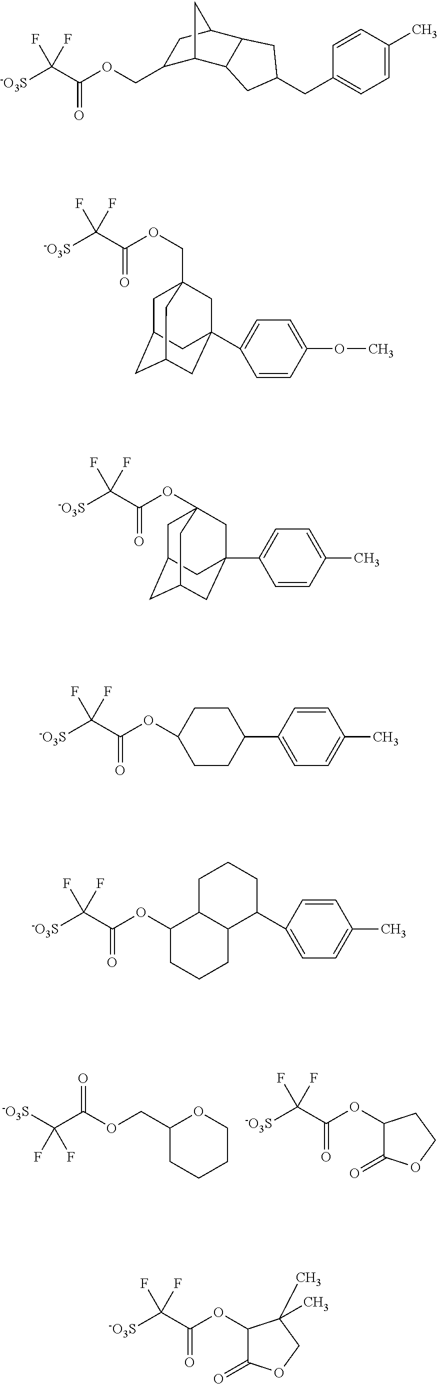

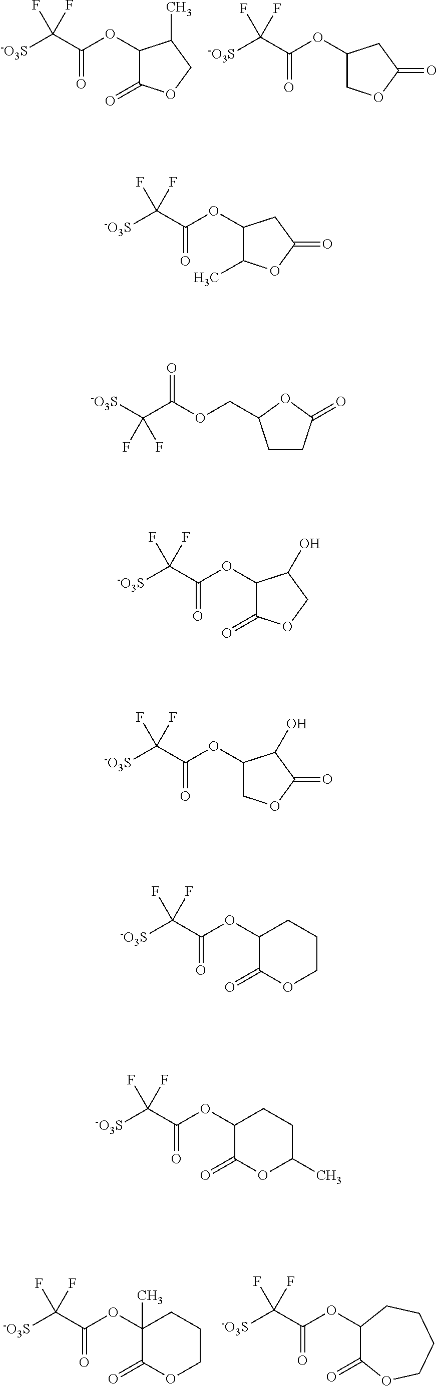

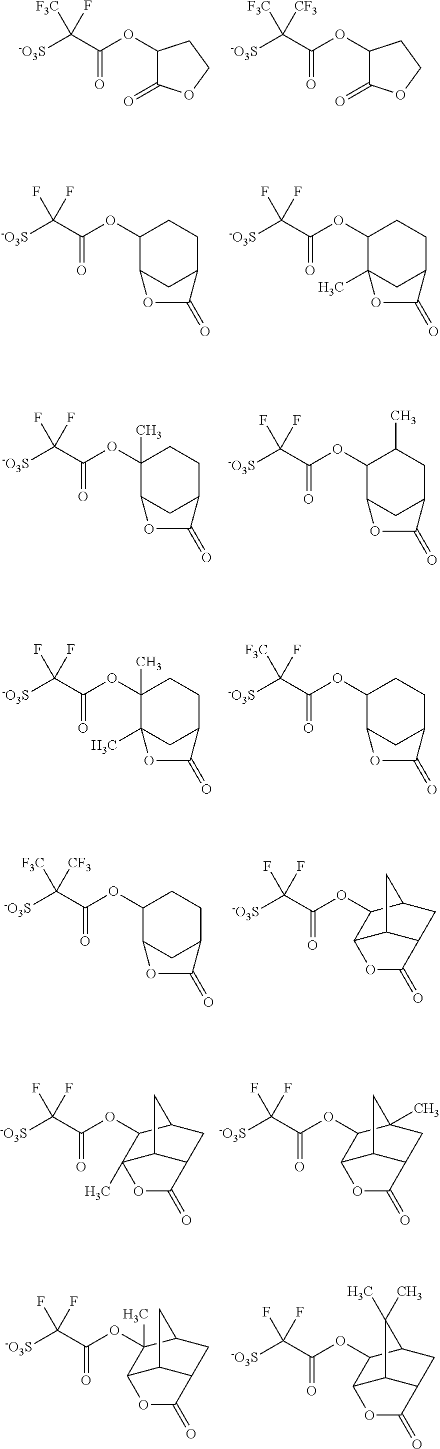

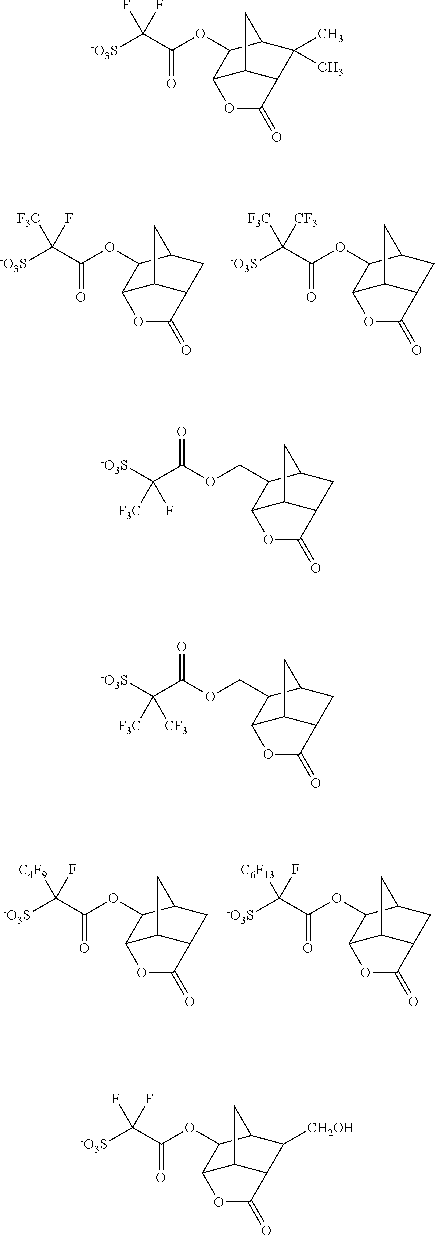

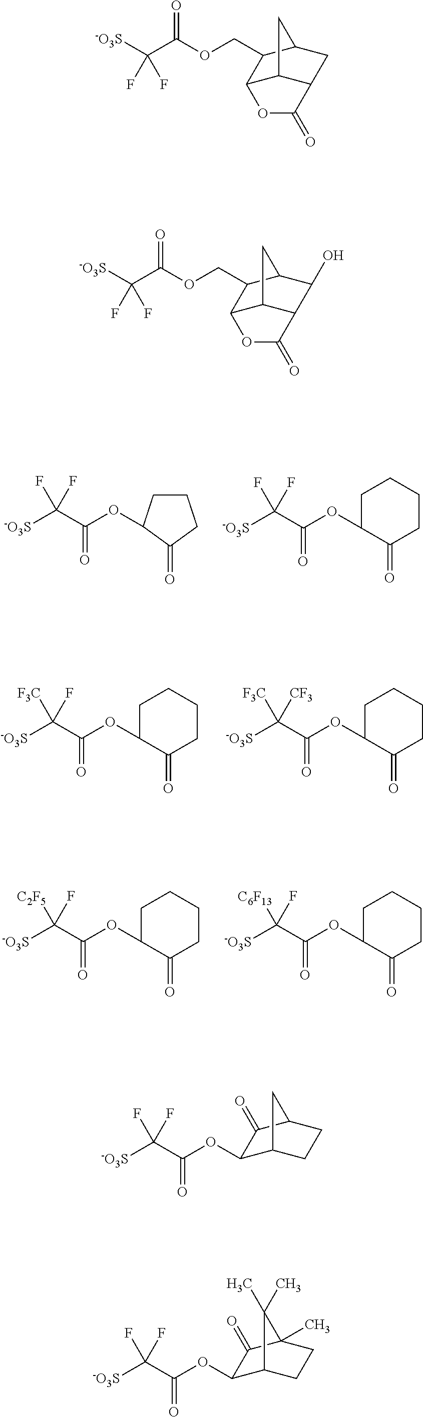

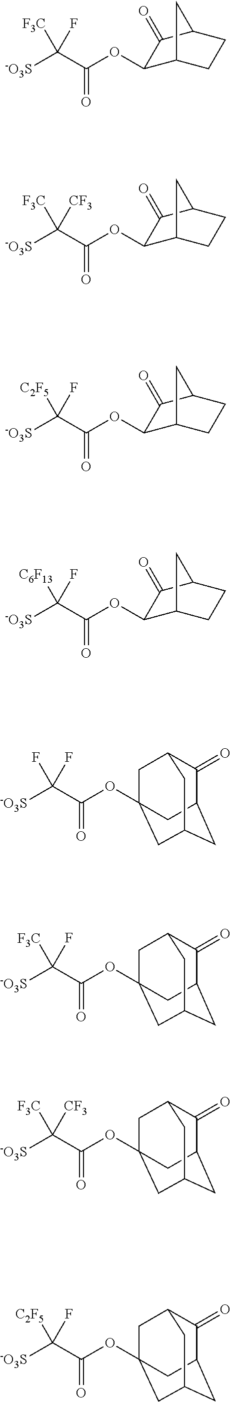

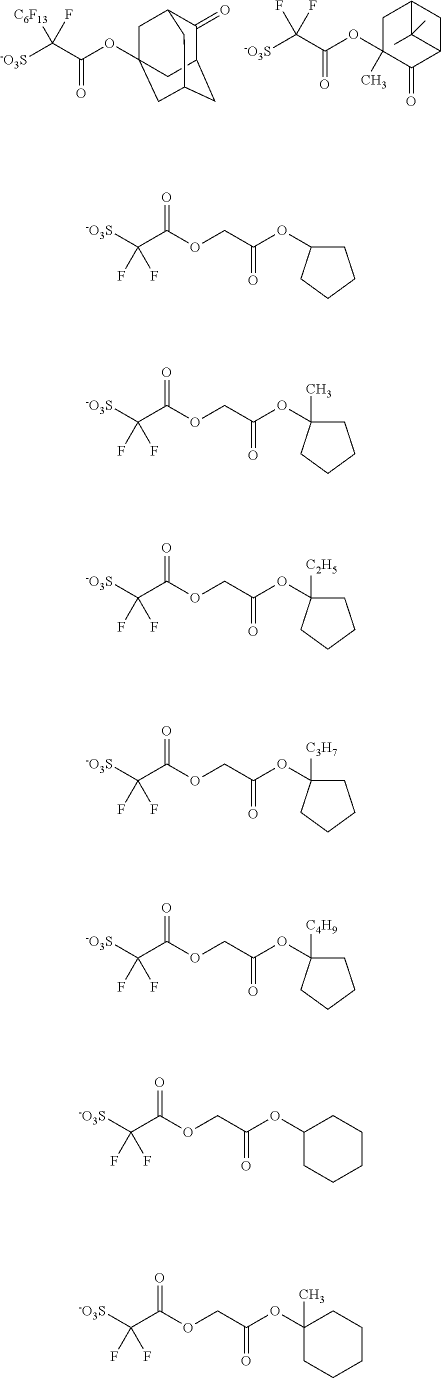

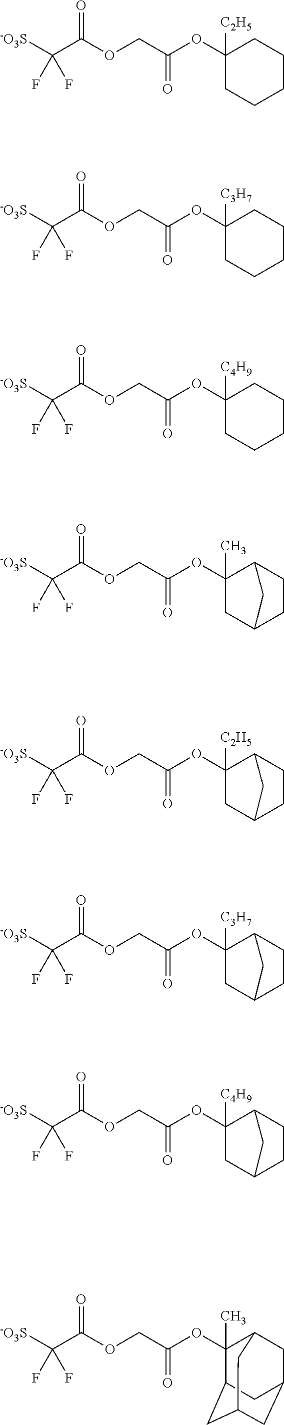

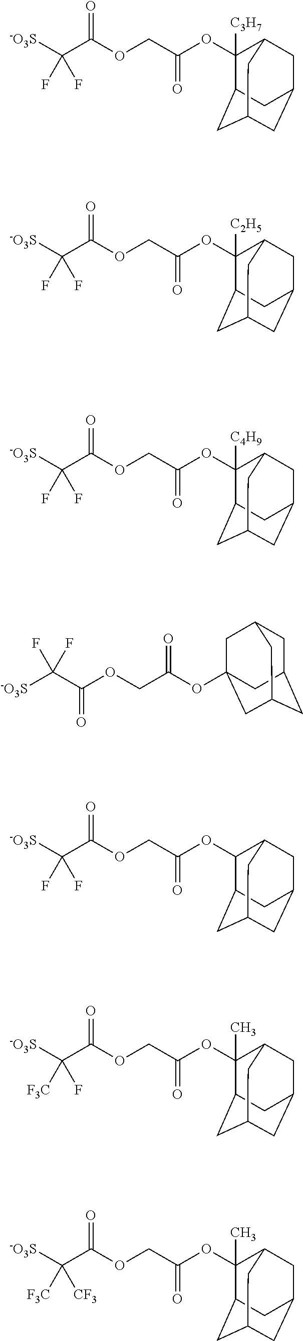

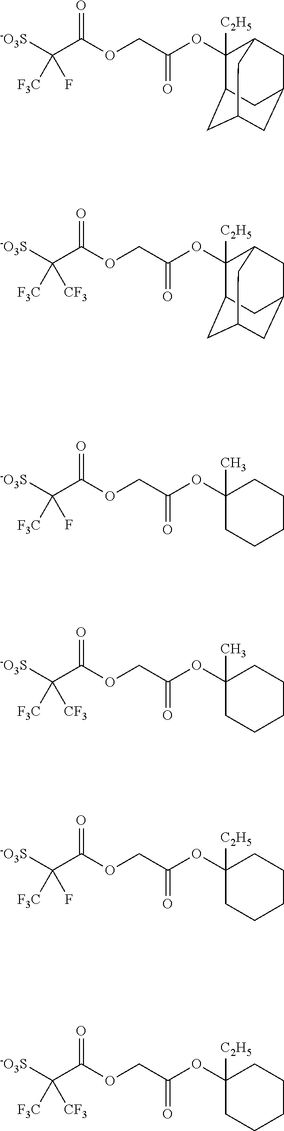

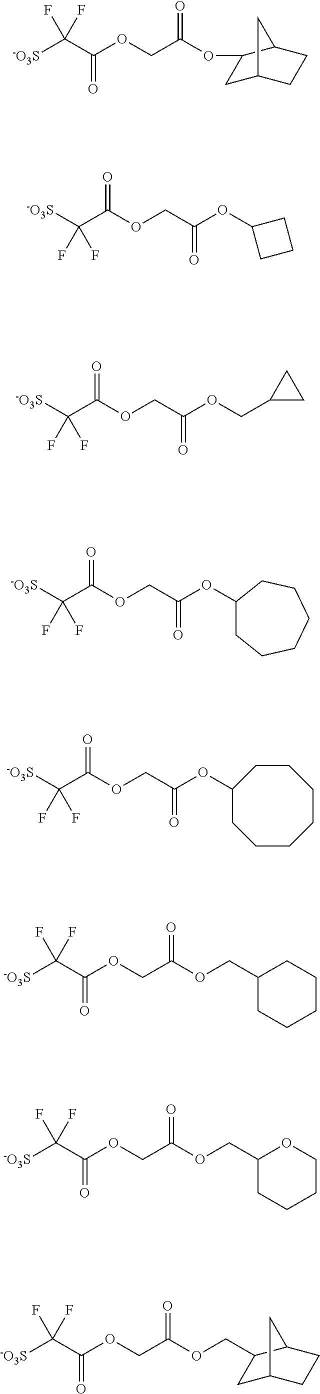

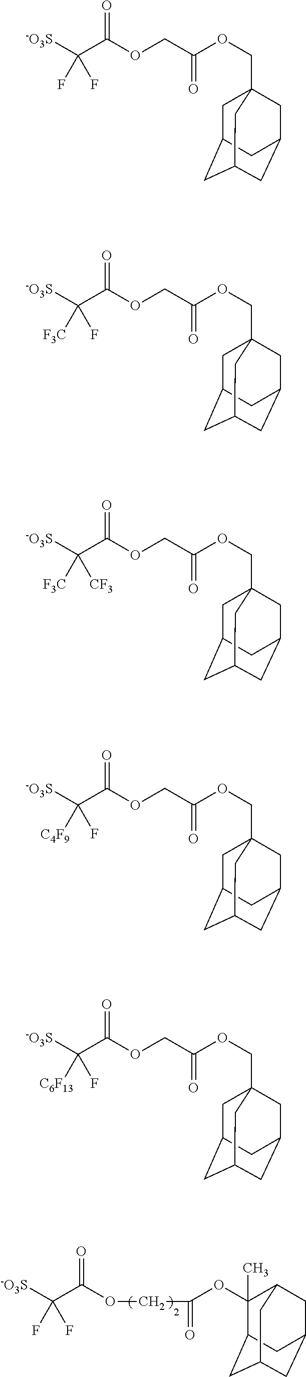

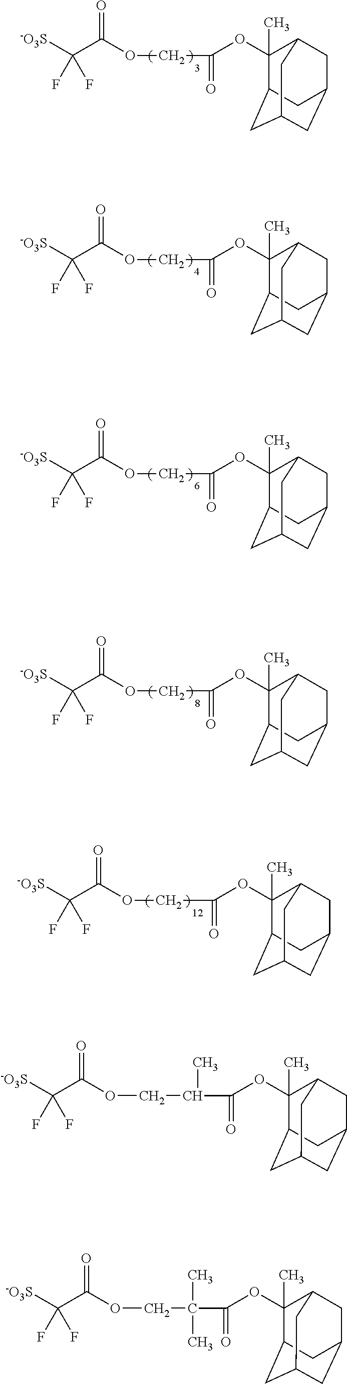

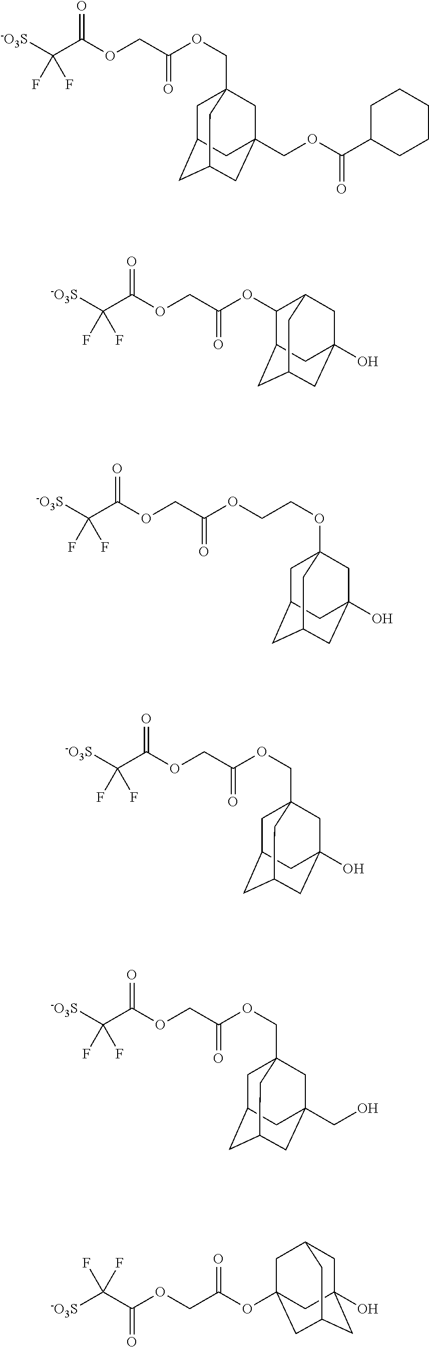

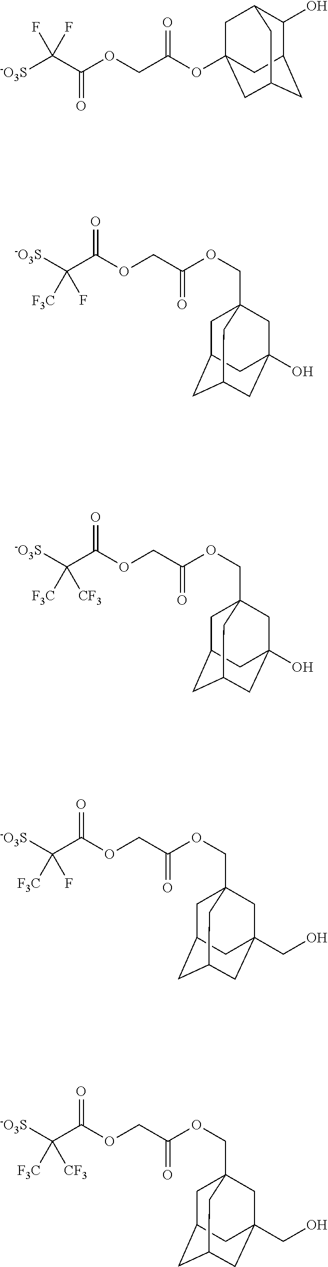

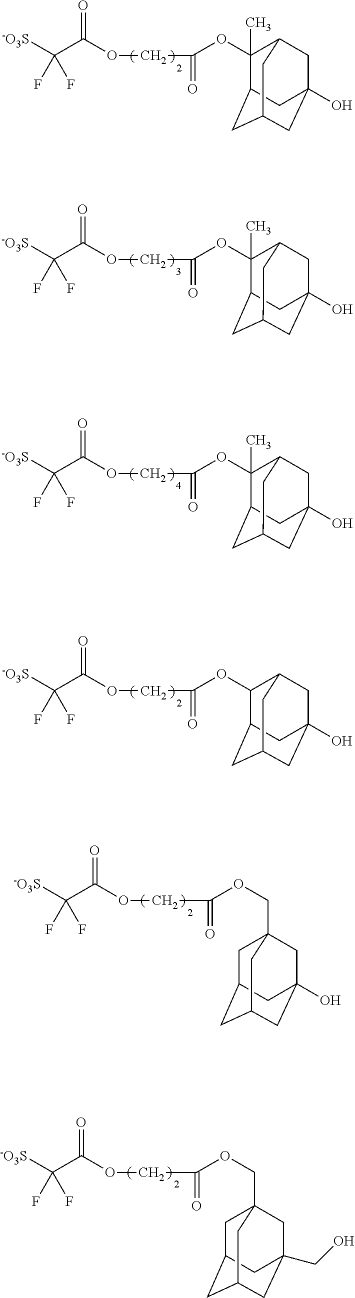

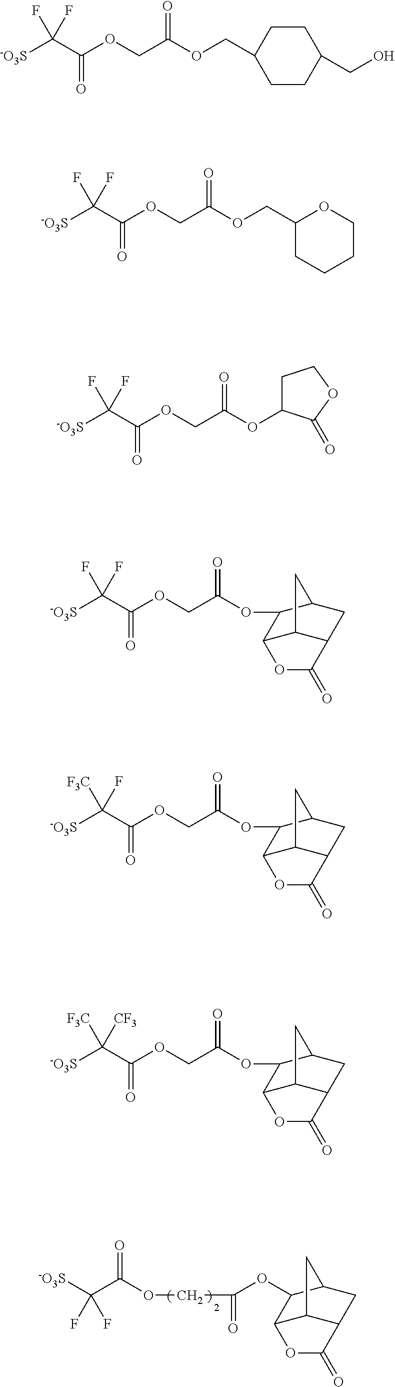

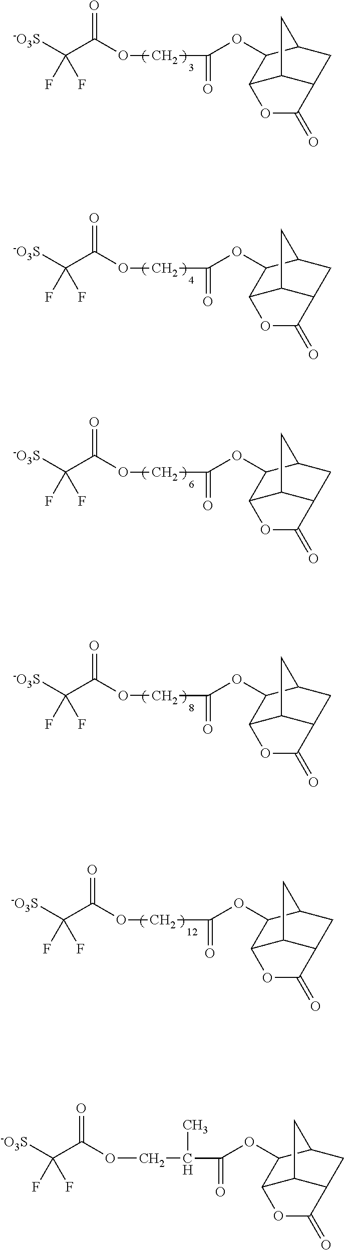

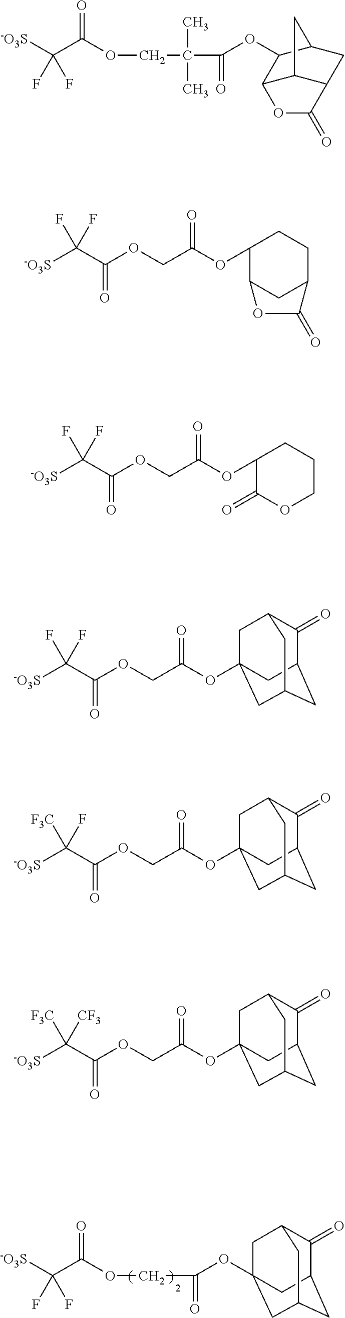

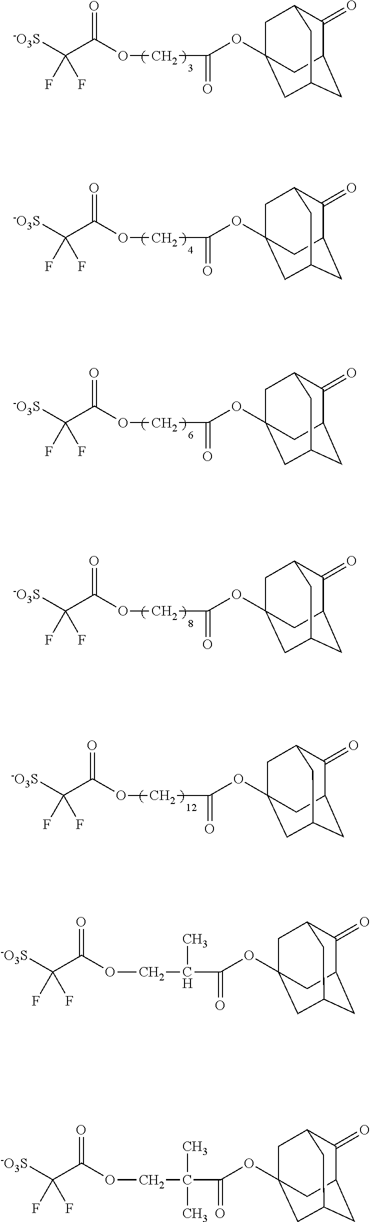

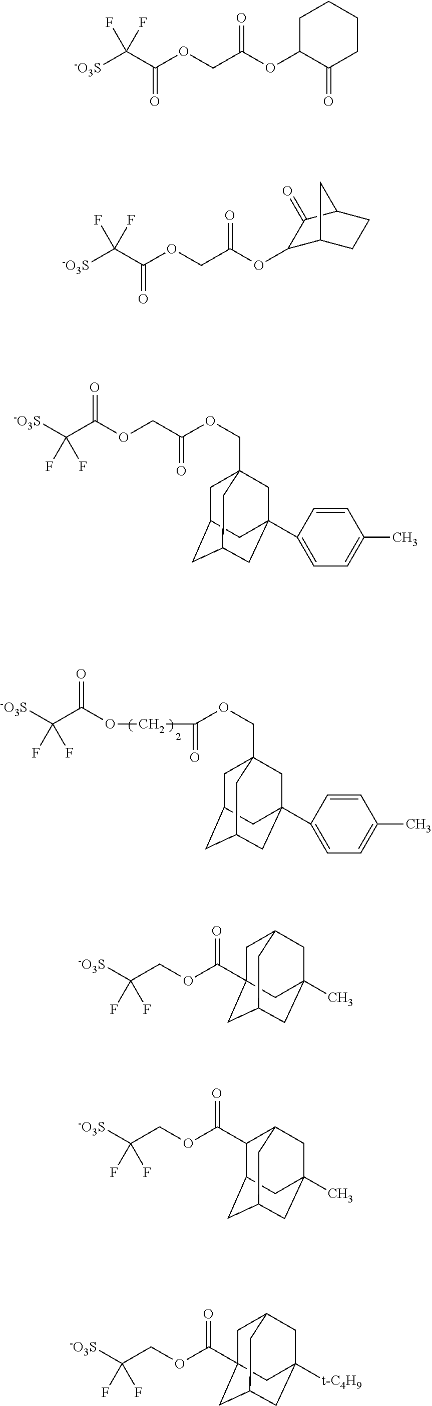

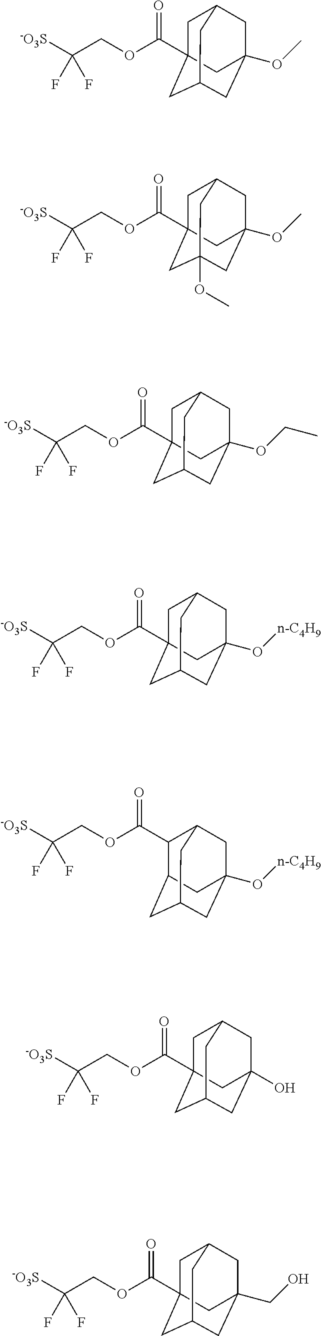

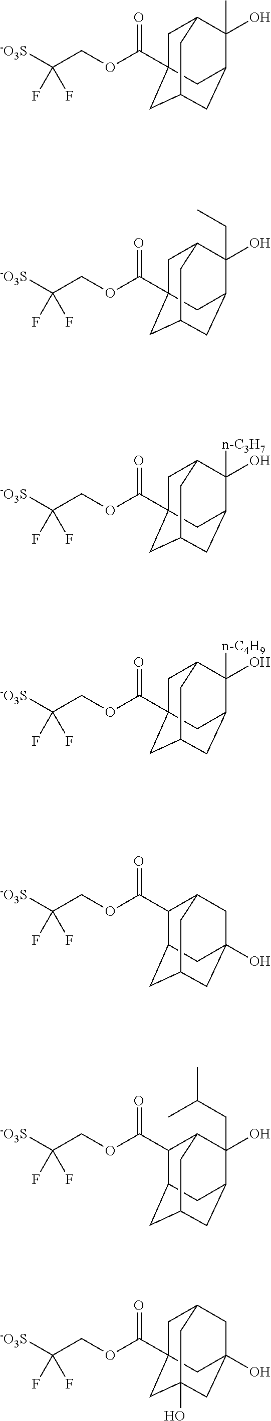

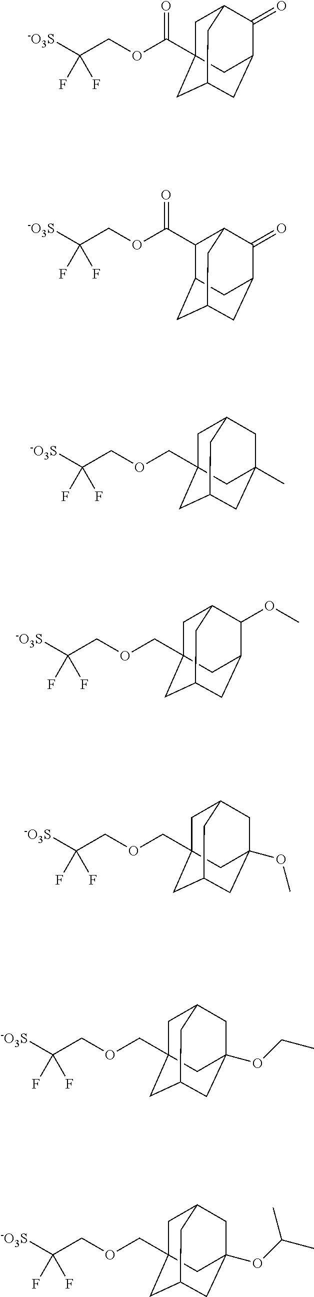

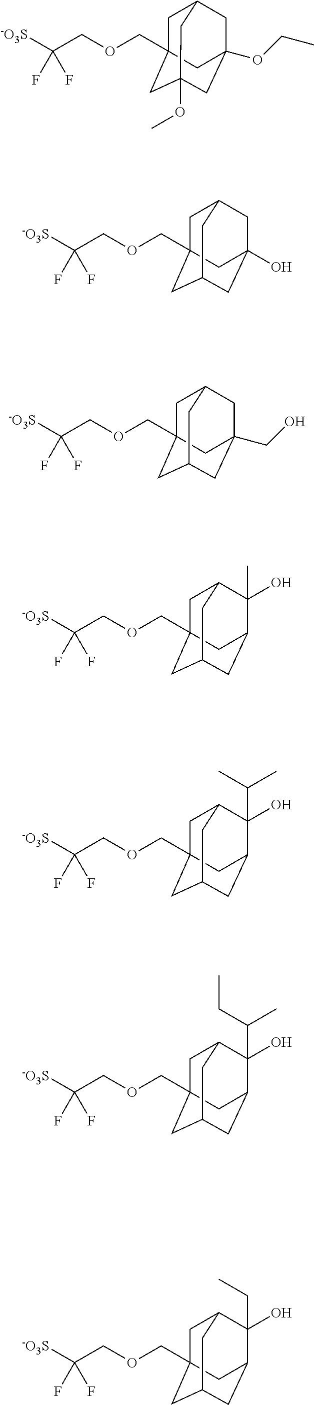

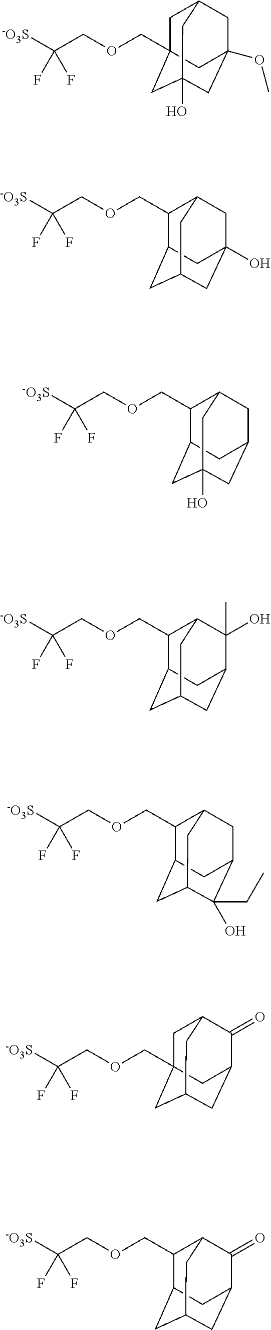

Among them, preferred are the following sulfonic anions.

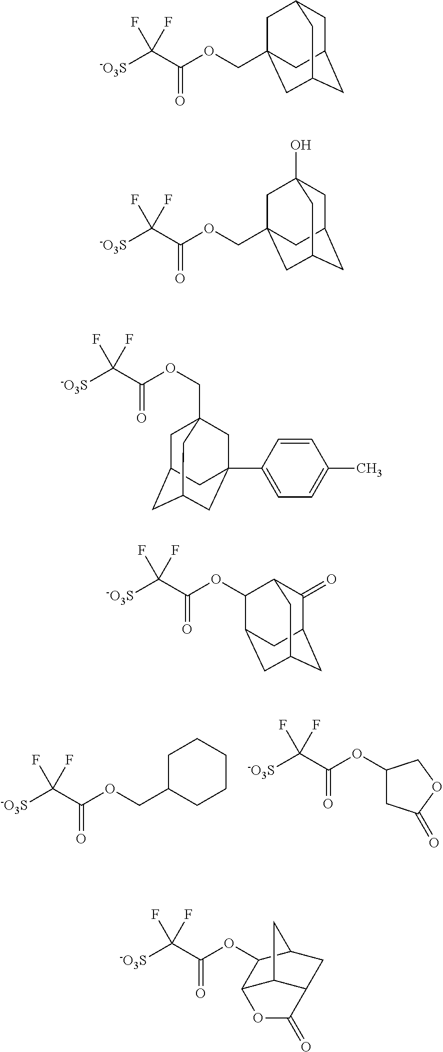

Examples of the organic cation represented by Z⁺ in the acid generator represented by the formula (B1) include an onium cation such as a sulfonium cation, an iodonium cation, an ammonium cation, a benzothiazolium cation and a phosphonium cation, and a sulfonium cation and an iodonium cation are preferable, and an arylsulfonium cation is more preferable.

Preferable examples of the organic cation represented by Z⁺ include the cations represented by the formulae (b2-1) to (b2-4):

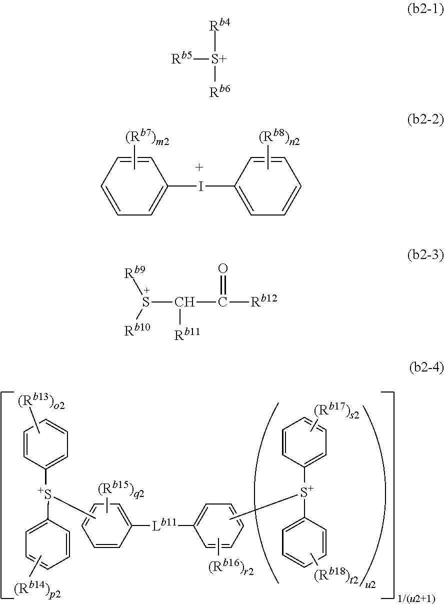

wherein R^{b4}, R^{b5} and R^{b6} independently represent a C1-C30 aliphatic hydrocarbon group which can have one or more substituents selected from the group consisting of a hydroxyl group, a C1-C12 alkoxy group and a C6-C18 aromatic hydrocarbon group, a C3-C36 saturated cyclic hydrocarbon group which can have one or more substituents selected from the group consisting of a halogen atom, a C2-C4 acyl group and a glycidyloxy group, or a C6-C18 aromatic hydrocarbon group which can have one or more substituents selected from the group consisting of a halogen atom, a hydroxyl group, a C1-C36 aliphatic hydrocarbon group, a C3-C36 saturated cyclic hydrocarbon group or a C1-C12 alkoxy group,
R^{b7} and R^{b8} are independently in each occurrence a hydroxyl group, a C1-C12 aliphatic hydrocarbon group or a C1-C12 alkoxy group, m2 and n2 independently represents an integer of 0 to 5,
R^{b9} and R^{b10} independently represent a C1-C36 aliphatic hydrocarbon group or a C3-C36 saturated cyclic hydrocarbon group, or R^{b9} and
R^{b10} are bonded to form a C2-C11 divalent acyclic hydrocarbon group which forms a ring together with the adjacent S⁺, and one or more —CH₂— in the divalent acyclic hydrocarbon group may be replaced by —CO—, —O— or —S—, and
R^{b11} represents a hydrogen atom, a C1-C36 aliphatic hydrocarbon group, a C3-C36 saturated cyclic hydrocarbon group or a C6-C18 aromatic hydrocarbon group, R^{b12} represents a C1-C12 aliphatic hydrocarbon group, a C3-C18 saturated cyclic hydrocarbon group or a C6-C18 aromatic hydrocarbon group and the aromatic hydrocarbon group can have one or more substituents selected from the group consisting of a C1-C12 aliphatic hydrocarbon group, a C1-C12 alkoxy group, a C3-C18 saturated cyclic hydrocarbon group and an acyloxy group, or R^{b11} and R^{b12} are bonded each other to form a C1-C10 divalent acyclic hydrocarbon group which forms a 2-oxocycloalkyl group together with the adjacent —CHCO—, and one or more —CH₂— in the divalent acyclic hydrocarbon group may be replaced by —CO—, —O— or —S—, and
R^{b13}, R^{b14}, R^{b15}, R^{b16}, R^{b17} and R^{b18} independently represent a hydroxyl group, a C1-C12 aliphatic hydrocarbon group or a C1-C12 alkoxy group, L^{b11} represents —S— or —O— and o2, p2, s2 and t2 each independently represents an integer of 0 to 5, q2 and r2 each independently represents an integer of 0 to 4, and u2 represents 0 or 1.

The aliphatic hydrocarbon group represented by R^{b9} to R^{b11} has preferably 1 to 12 carbon atoms. The saturated cyclic hydrocarbon group represented by R^{b9} to R^{b11} has preferably 3 to 36 carbon atoms and more preferably 4 to 12 carbon atoms.

Examples of the aliphatic hydrocarbon group and the aromatic hydrocarbon group include the same as described above. Preferable examples of the aliphatic hydrocarbon group include a methyl group, an ethyl group, a propyl group, an isopropyl group, a butyl group, a sec-butyl group, a tert-butyl group, a pentyl group, a hexyl group, an octyl group and a 2-ethylhexyl group. A C4-C12 cyclic aliphatic hydrocarbon group is preferable. Preferable examples of the cyclic aliphatic hydrocarbon group include a cyclopropyl group, a cyclobutyl group, a cyclopentyl group, a cyclohexyl group, a cycloheptyl group, a cyclodecyl group, a 2-alkyl-a-adamantyl group, a 1-(1-adamantyl)-1-alkyl group and an isobornyl group. Preferable examples of the aromatic group include a phenyl group, a 4-methylphenyl group, a 4-ethylphenyl group, a 4-tert-butylphenyl group, a 4-cyclohexylphenyl group, a 4-methoxyphenyl group, a biphenyl group and a naphthyl group. Examples of the aliphatic hydrocarbon group having an aromatic hydrocarbon group include a benzyl group. Examples of the alkoxy group include a methoxy group, an ethoxy group, a propoxy group, an isopropoxy group, a butoxy group, a sec-butoxy group, a tert-butoxy group, a pentyloxy group, a hexyloxy group, a heptyloxy group, an octyloxy group, a 2-ethylhexyloxy group, a nonyloxy group, a decyloxy group, an undecyloxy group and a dodecyloxy group.

Examples of the C3-C12 divalent acyclic hydrocarbon group formed by bonding R^{b9} and R^{b10} include a trimethylene group, a tetramethylene group and a pentamethylene group. Examples of the ring group formed together with the adjacent S⁺ and the divalent acyclic hydrocarbon group include a thiolan-1-ium ring (tetrahydrothiphenium ring), a thian-1-ium ring and a 1,4-oxathian-4-iumring. AC3-C7 divalent acyclic hydrocarbon group is preferable.

Examples of the C1-C10 divalent acyclic hydrocarbon group formed by bonding R^{b11} and R^{b12} include a methylene group, an ethylene group, a trimethylene group, a tetramethylene group and a pentamethylene group and examples of the ring group include the followings.

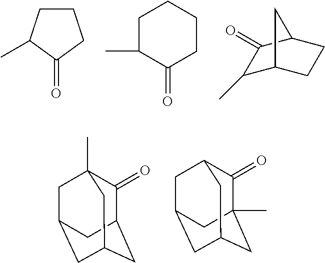

A C1-C5 divalent acyclic hydrocarbon group is preferable.

Among the above-mentioned cations, preferred is the cation represented by the formula (b2-1), and more preferred is the cation represented by the formula (b2-1-1). A triphenylsulfonium cation is especially preferable.

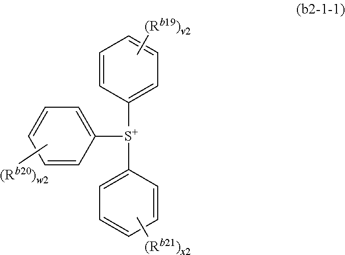

wherein R^{b19}, R^{b20} and R^{b21} are independently in each occurrence a halogen atom, a hydroxyl group, a C1-C36 aliphatic hydrocarbon group, a C3-C36 saturated cyclic hydrocarbon group or a C1-C12 alkoxy group, and one or more hydrogen atoms of the aliphatic hydrocarbon group can be replaced by a hydroxyl group, a C1-C12 alkoxy group or a C6-C18 aromatic hydrocarbon group, and one or more hydrogen atoms of the saturated cyclic hydrocarbon group can be replaced by a halogen atom, a glycidyloxy group or a C2-C4 acyl group, and v2, w2 and x2 independently each represent an integer of 0 to 5.

The aliphatic hydrocarbon group has preferably 1 to 12 carbon atoms, and the saturated cyclic hydrocarbon group has preferably 4 to 36 carbon atoms, and v2, w2 and x2 independently each preferably represent 0 or 1.

It is preferred that R^{b19}, R^{b20} and R^{b21} are independently in each occurrence a halogen atom, a hydroxyl group, a C1-C12 alkyl group or a C1-C12 alkoxy group and v2, w2 and x2 independently each represent an integer of 0 to 5, and it is more preferred that R^{b19}, R^{b20} and R^{b21} are independently in each occurrence a fluorine atom, a hydroxyl group, a C1-C12 alkyl group or a C1-C12 alkoxy group, and v2, w2 and x2 independently each preferably represent 0 or 1.

Examples of the cation represented by the formula (b2-1) include the followings.

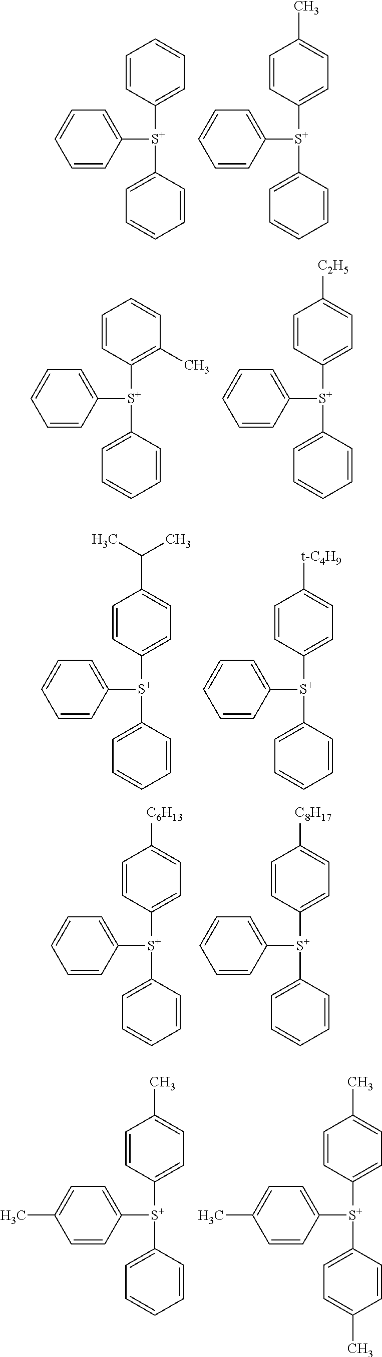

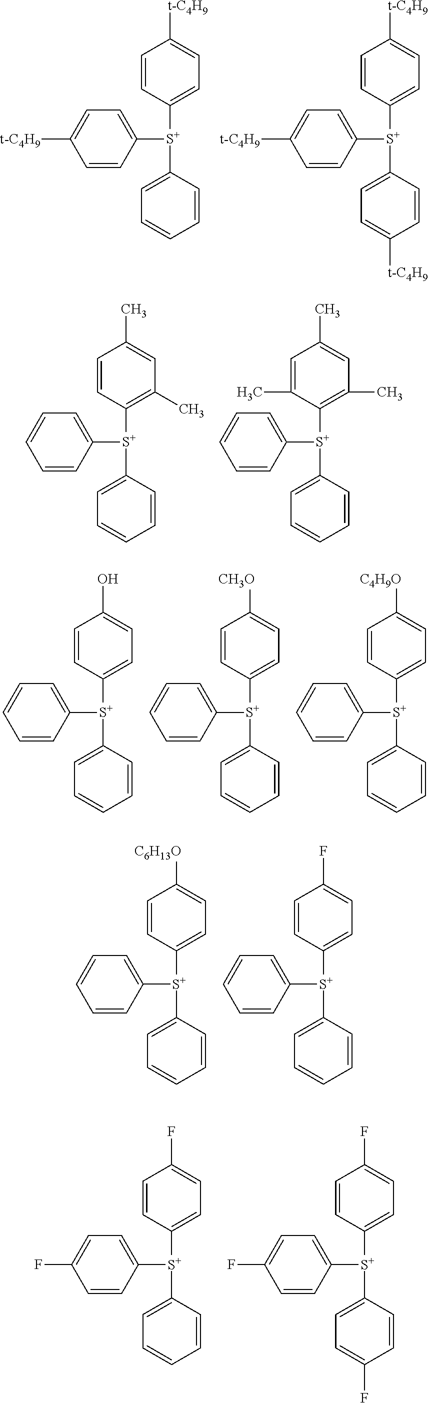

Examples of the cation represented by the formula (b2-2) include the followings.

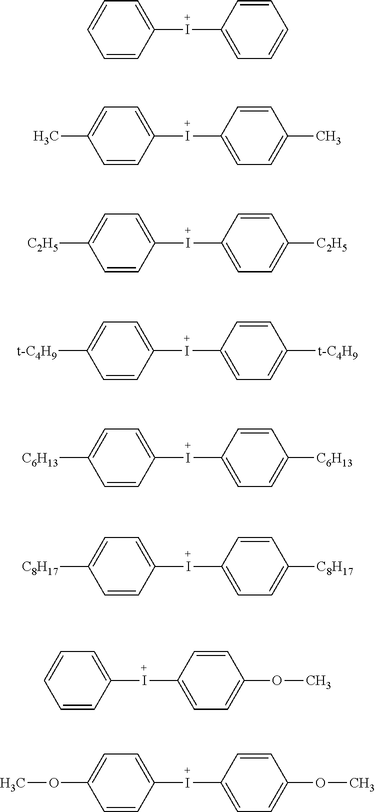

Examples of the cation represented by the formula (b2-3) include the followings.

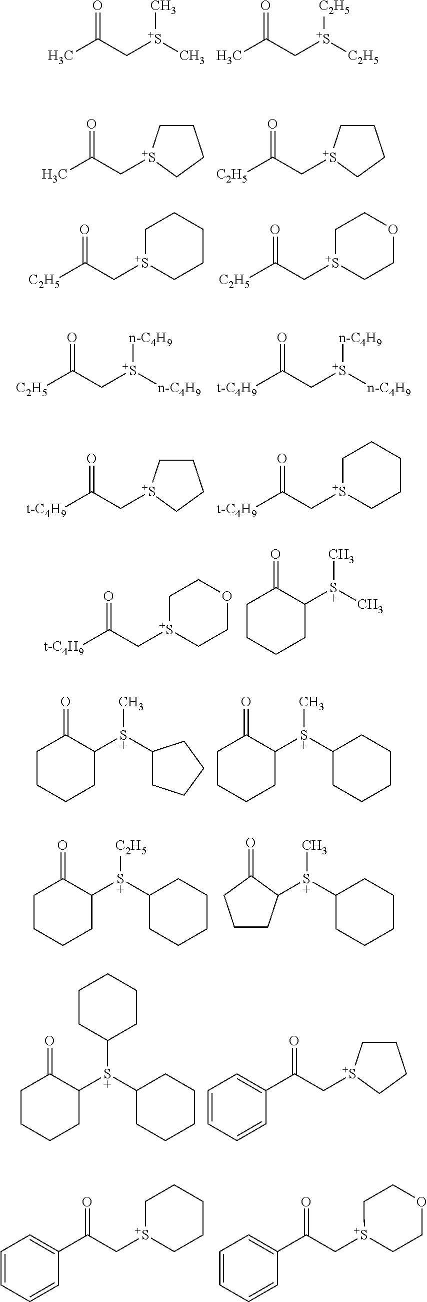

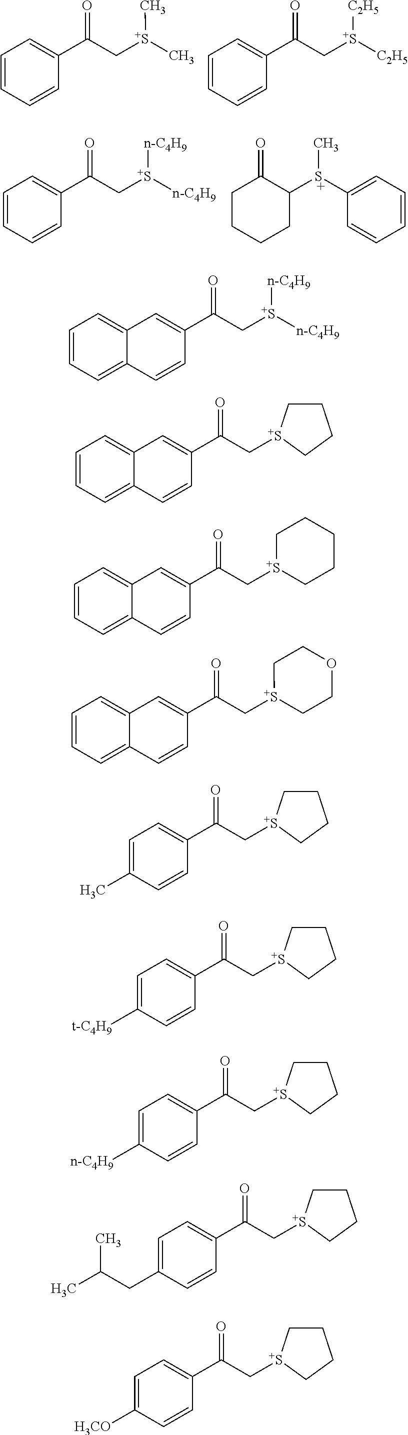

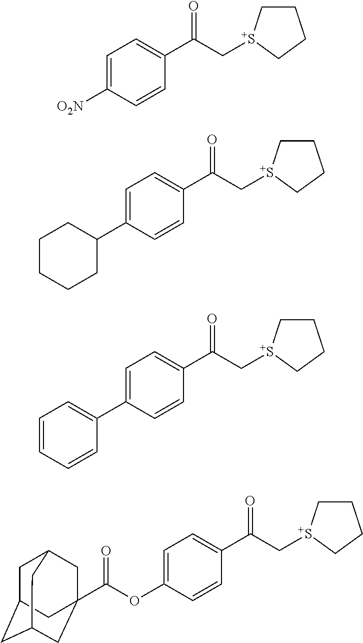

Examples of the cation represented by the formula (b2-4) include the followings.

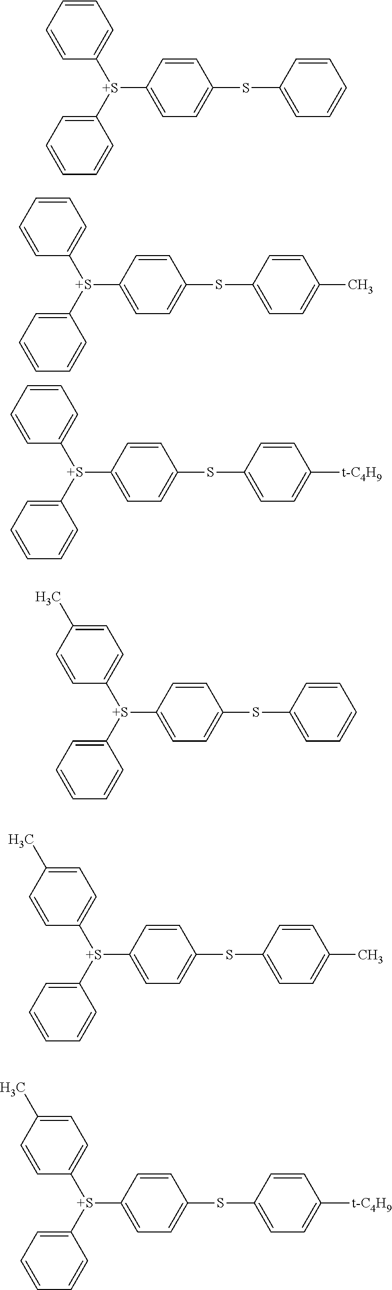

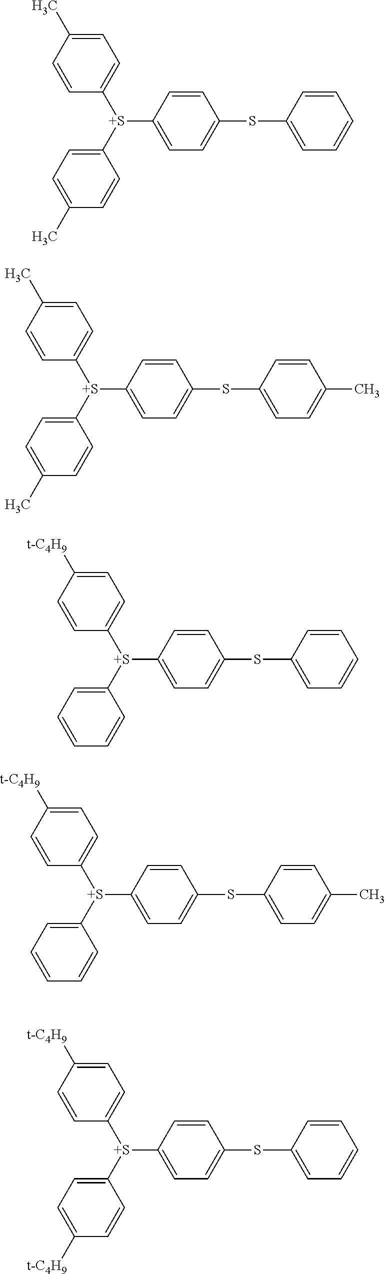

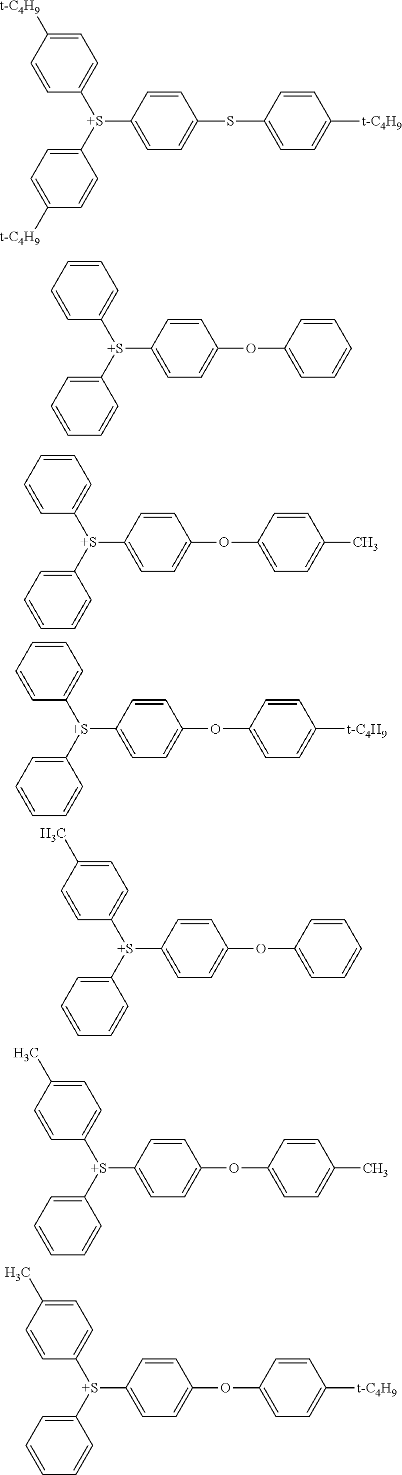

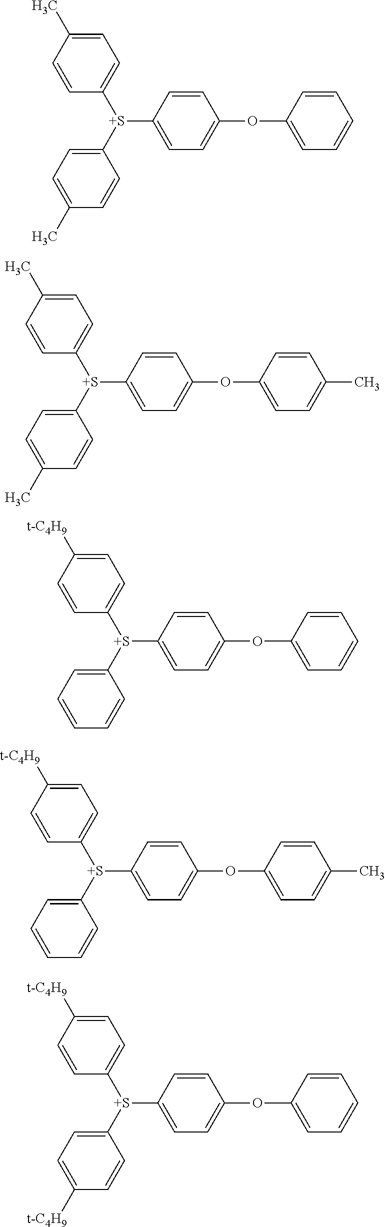

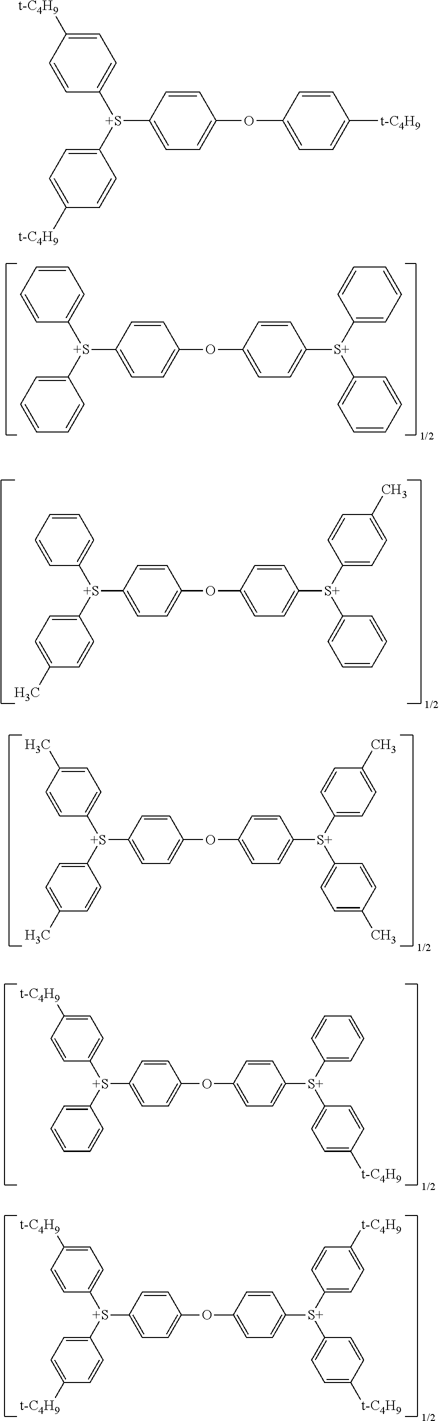

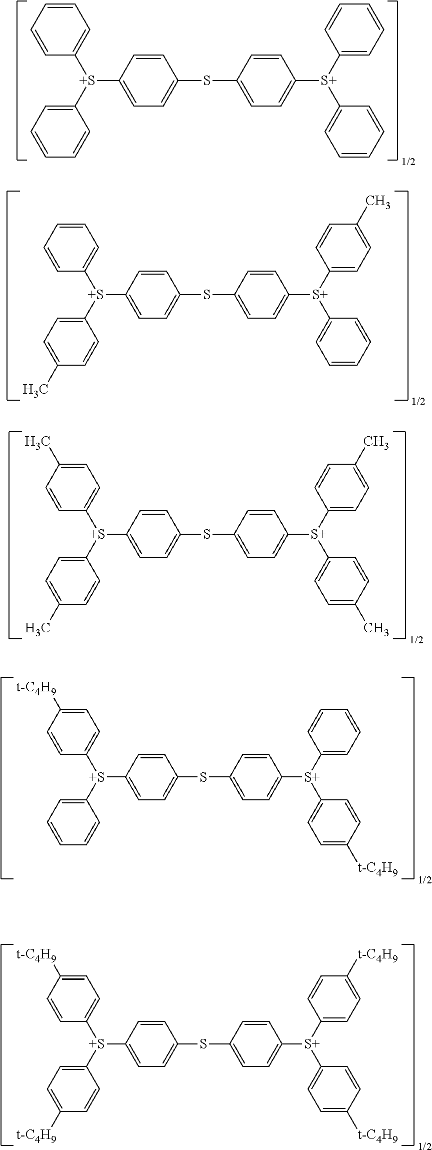

Examples of the acid generator represented by the formula (B1) include an acid generator wherein the anion is any one of the above-mentioned anions and the cation is any one of the above-mentioned organic cations. Preferable examples of the acid generator include a combination of any one of anions represented by the formulae (b1-1-1) to (b1-1-9) and the cation represented by the formulae (b2-1-1), and a combination of any one of anions represented by the formulae (b1-1-3) to (b1-1-5) and the cation represented by the formulae (b2-3).

The acid generator represented by the formulae (B1-1) to (B1-17) are preferable, and the acid generators represented by the formulae (B1-1), (B1-2), (B1-6), (B1-11), (B1-12), (B1-13) and (B1-14) are more preferable.

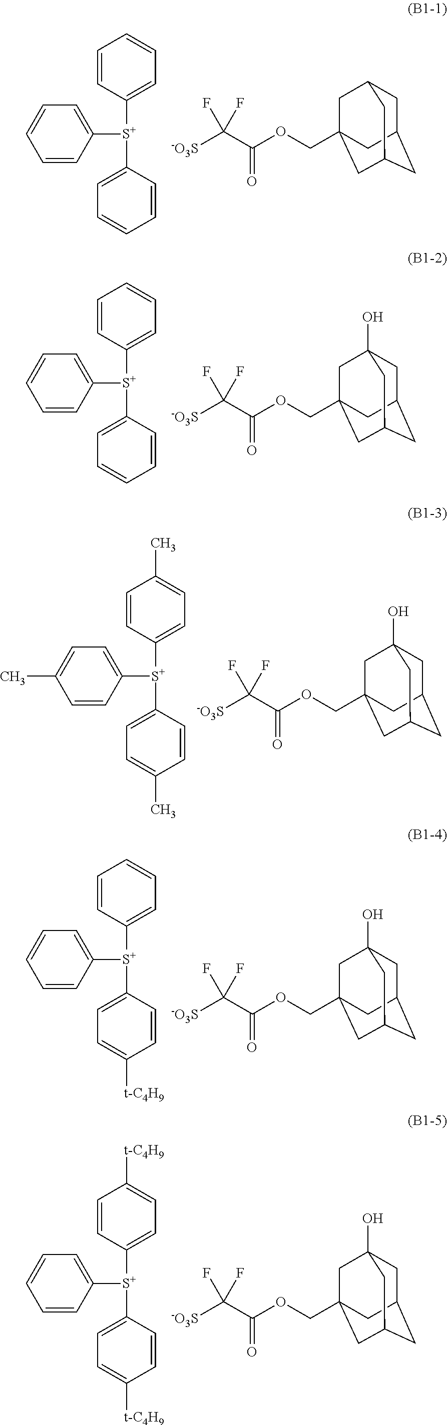

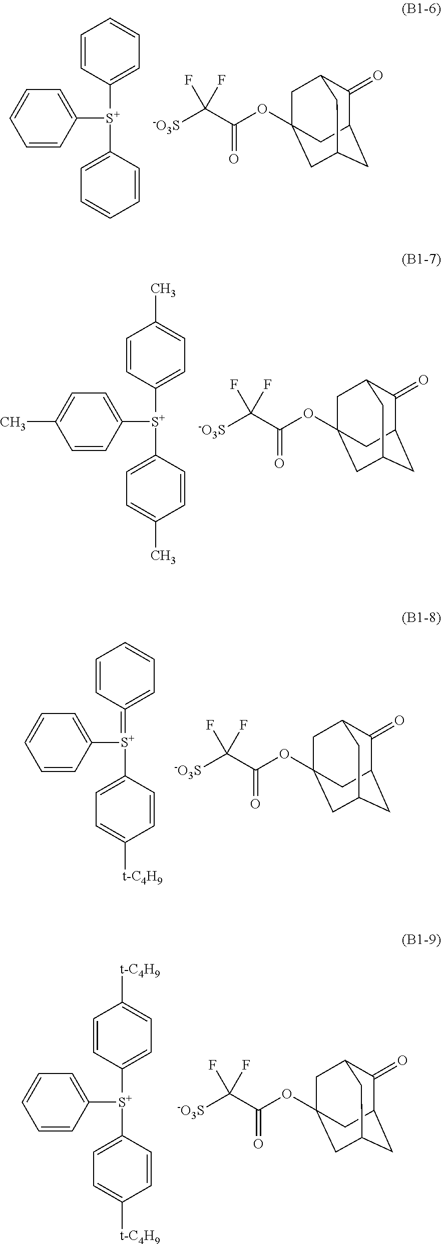

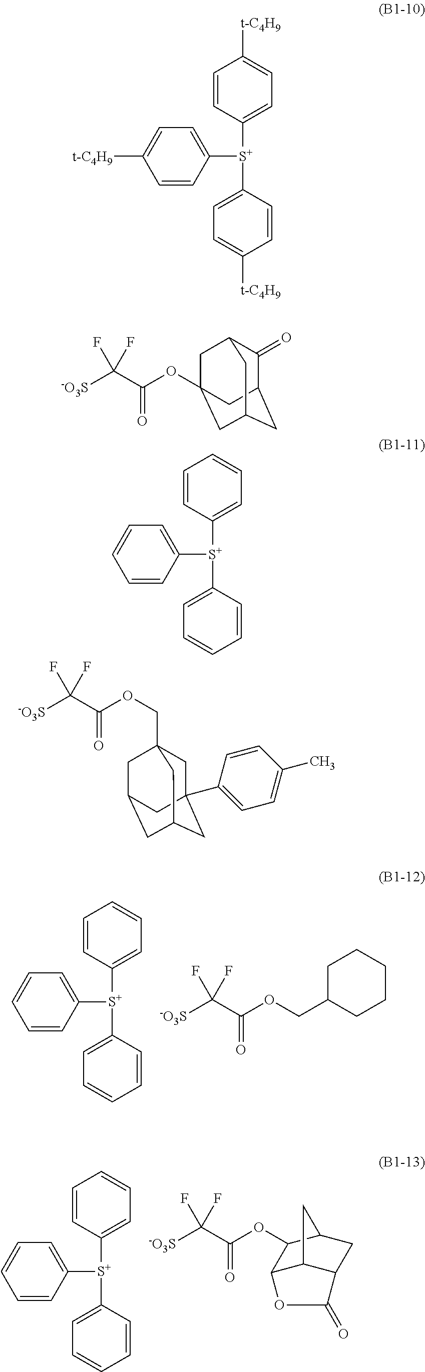

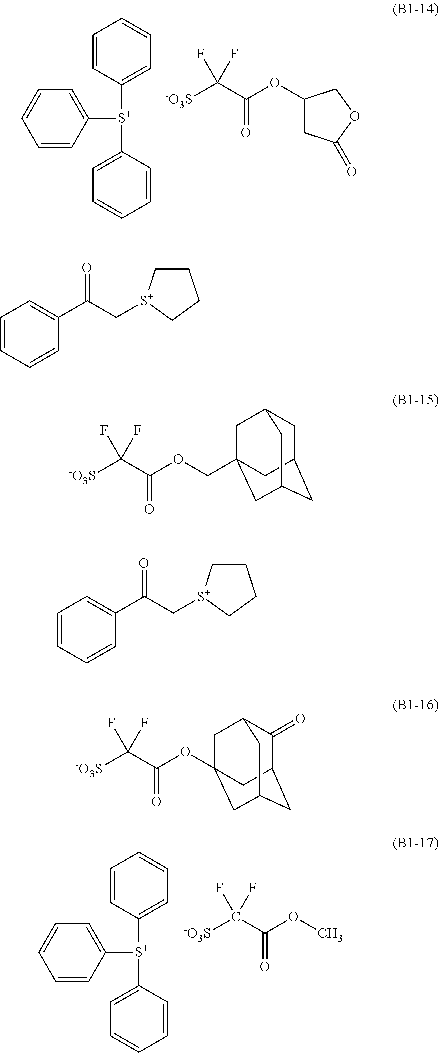

Two or more kinds of the acid generator represented by the formula (B1) can be used in combination.

The content of the acid generator represented by the formula (B1) in the photoresist composition is usually 1 part by weight or more and preferably 3 parts by weight or more per 100 parts by weight of COMPOUND (I), and it is usually 30 parts by weight or less and preferably 25 parts by weight or less per 100 parts by weight of COMPOUND (I).

The photoresist composition of the present invention can contain one or more acid generators other than the acid generator represented by the formula (B1).

The photoresist composition of the present invention can contain a basic compound as a quencher.

The basic compound is preferably a basic nitrogen-containing organic compound, and examples thereof include an amine compound such as an aliphatic amine and an aromatic amine and an ammonium salt. Examples of the aliphatic amine include a primary amine, a secondary amine and a tertiary amine. Examples of the aromatic amine include an aromatic amine in which aromatic ring has one or more amino groups such as aniline and a heteroaromatic amine such as pyridine. Preferable examples thereof include an aromatic amine represented by the formula (C2):

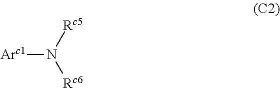

wherein Ar^{c1} represents an aromatic hydrocarbon group, and R^{c5} and R^{c6} independently represent a hydrogen atom, an aliphatic hydrocarbon group, a saturated cyclic hydrocarbon group or an aromatic hydrocarbon group, and the aliphatic hydrocarbon group, the saturated cyclic hydrocarbon group and the aromatic hydrocarbon group can have one or more substituents selected from the group consisting of a hydroxyl group, an amino group, an amino group having one or two C1-C4 alkyl groups and a C1-C6 alkoxy group.

The aliphatic hydrocarbon group is preferably an alkyl group and the saturated cyclic hydrocarbon group is preferably a cycloalkyl group. The aliphatic hydrocarbon group preferably has 1 to 6 carbon atoms. The saturated cyclic hydrocarbon group preferably has 5 to 10 carbon atoms. The aromatic hydrocarbon group preferably has 6 to 10 carbon atoms.

As the aromatic amine represented by the formula (C2), an amine represented by the formula (C2-1):

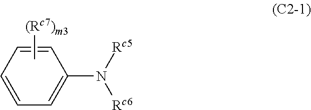

wherein R^{c5} and R^{c6} are the same as defined above, and R^{c7} is independently in each occurrence an aliphatic hydrocarbon group, an alkoxy group, a saturated cyclic hydrocarbon group or an aromatic hydrocarbon group, and the aliphatic hydrocarbon group, the alkoxy group, the saturated cyclic hydrocarbon group and the aromatic hydrocarbon group can have one or more substituents selected from the group consisting of a hydroxyl group, an amino group, an amino group having one or two C1-C4 alkyl groups and a C1-C6 alkoxy group, and m3 represents an integer of 0 to 3, is preferable. The aliphatic hydrocarbon group is preferably an alkyl group and the saturated cyclic hydrocarbon group is preferably a cycloalkyl group. The aliphatic hydrocarbon group preferably has 1 to 6 carbon atoms. The saturated cyclic hydrocarbon group preferably has 5 to 10 carbon atoms. The aromatic hydrocarbon group preferably has 6 to 10 carbon atoms. The alkoxy group preferably has 1 to 6 carbon atoms.

Examples of the aromatic amine represented by the formula (C2) include 1-naphthylamine, 2-naphthylamine, aniline, diisopropylaniline, 2-methylaniline, 3-methylaniline, 4-methylaniline, 4-nitroaniline, N-methylaniline, N,N-dimethylaniline, and diphenylamine, and among them, preferred is diisopropylaniline and more preferred is 2,6-diisopropylaniline.

Other examples of the basic compound include amines represented by the formulae (C3) to (C11):

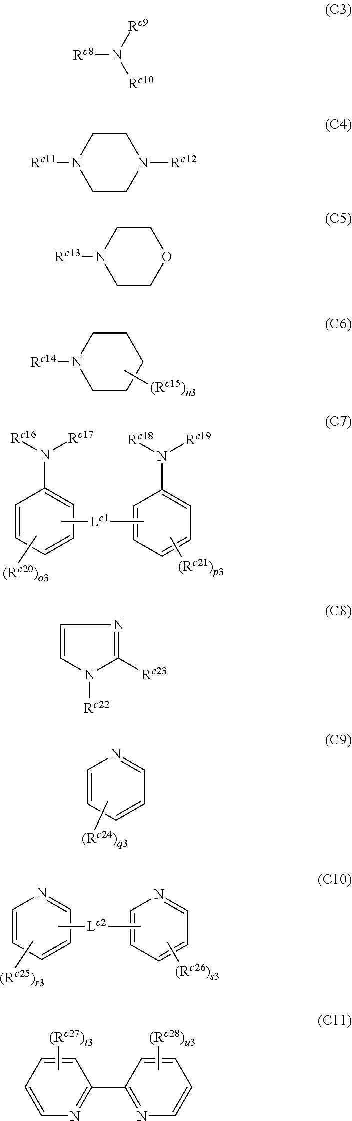

wherein R^{c8}, R^{c20}, R^{c21}, and R^{c23} to R^{c28} independently represent an aliphatic hydrocarbon group, an alkoxy group, a saturated cyclic hydrocarbon group or an aromatic hydrocarbon group, and the aliphatic hydrocarbon group, the alkoxy group, the saturated cyclic hydrocarbon group and the aromatic hydrocarbon group can have one or more substituents selected from the group consisting of a hydroxyl group, an amino group, an amino group having one or two C1-C4 alkyl groups and a C1-C6 alkoxy group,
R^{c9}, R^{c10}, R^{c11} to R^{c14}, R^{c16} to R^{c19}, and R^{c22} independently represents a hydrogen atom, an aliphatic hydrocarbon group, a saturated cyclic hydrocarbon group or an aromatic hydrocarbon group, and the aliphatic hydrocarbon group, the saturated cyclic hydrocarbon group and the aromatic hydrocarbon group can have one or more substituents selected from the group consisting of a hydroxyl group, an amino group, an amino group having one or two C1-C4 alkyl groups and a C1-C6 alkoxy group,
R^{c15} is independently in each occurrence an aliphatic hydrocarbon group, a saturated cyclic hydrocarbon group or an alkanoyl group, L^{c1} and L^{c2} independently represents a divalent aliphatic hydrocarbon group, —CO—, —C(═NH)—, —C(═NR^{c3})—, —S—, —S—S— or a combination thereof and R^{c3} represents a C1-C4 alkyl group,
O3 to u3 each independently represents an integer of 0 to 3 and
n3 represents an integer of 0 to 8.

The aliphatic hydrocarbon group has preferably 1 to 6 carbon atoms, and the saturated cyclic hydrocarbon group has preferably 3 to 6 carbon atoms, and the alkanoyl group has preferably 2 to 6 carbon atoms, and the divalent aliphatic hydrocarbon group has preferably 1 to 6 carbon atoms. The divalent aliphatic hydrocarbon group is preferably an alkylene group.

Examples of the amine represented by the formula (C3) include hexylamine, heptylamine, octylamine, nonylamine, decylamine, dibutylamine, dipentylamine, dihexylamine, diheptylamine, dioctylamine, dinonylamine, didecylamine, triethylamine, trimethylamine, tripropylamine, tributylamine, tripentylamine, trihexylamine, triheptylamine, trioctylamine, trinonylamine, tridecylamine, methyldibutylamine, methyldipentylamine, methyldihexylamine, methyldicyclohexylamine, methyldiheptylamine, methyldioctylamine, methyldinonylamine, methyldidecylamine, ethyldibutylamine, ethydipentylamine, ethyldihexylamine, ethydiheptylamine, ethyldioctylamine, ethyldinonylamine, ethyldidecylamine, dicyclohexylmethylamine, tris[2-(2-methoxyethoxy)ethyl]amine, triisopropanolamine, ethylenediamine, tetramethylenediamine, hexamethylenediamine, 4,4′-diamino-1,2-diphenylethane, 4,4′-diamino-3,3′-dimethyldiphenylmethane and 4,4′-diamino-3,3′-diethyldiphenylmethane.

Examples of the amine represented by the formula (C4) include piperazine. Examples of the amine represented by the formula (C5) include morpholine. Examples of the amine represented by the formula (C6) include piperidine and hindered amine compounds having a piperidine skeleton as disclosed in JP 11-52575 A. Examples of the amine represented by the formula (C7) include 2,2′-methylenebisaniline. Examples of the amine represented by the formula (C8) include imidazole and 4-methylimidazole. Examples of the amine represented by the formula (C9) include pyridine and 4-methylpyridine. Examples of the amine represented by the formula (C10) include di-2-pyridyl ketone, 1,2-di(2-pyridyl)ethane, 1,2-di(4-pyridyl)ethane, 1,3-di(4-pyridyl)propane, 1,2-bis(2-pyridyl)ethene, 1,2-bis(4-pyridyl)ethene, 1,2-di(4-pyridyloxy)ethane, 4,4′-dipyridyl sulfide, 4,4′-dipyridyl disulfide, 2,2′-dipyridylamine and 2,2′-dipicolylamine. Examples of the amine represented by the formula (C11) include bipyridine.

When the photoresist composition contains the basic compound, the content thereof is usually 0.01 to 1% by weight based on sum of solid component.

The photoresist composition of the present invention usually contains one or more solvents. Examples of the solvent include a glycol ether ester such as ethyl cellosolve acetate, methyl cellosolve acetate and propylene glycol monomethyl ether acetate; a glycol ether such as propylene glycol monomethyl ether; an acyclic ester such as ethyl lactate, butyl acetate, amyl acetate and ethyl pyruvate; a ketone such as acetone, methyl isobutyl ketone, 2-heptanone and cyclohexanone; and a cyclic ester such as γ-butyrolactone.

The amount of the solvent is usually 90% by weight or more, preferably 92% by weight or more preferably 94% by weight or more based on total amount of the photoresist composition of the present invention. The amount of the solvent is usually 99.9% by weight or less and preferably 99% by weight or less based on total amount of the photoresist composition of the present invention.

The photoresist composition of the present invention can contain, if necessary, a small amount of various additives such as a sensitizer, a dissolution inhibitor, other polymers, a surfactant, a stabilizer and a dye as long as the effect of the present invention is not prevented.

The photoresist composition of the present invention is useful for a chemically amplified photoresist composition.

A photoresist pattern can be produced by the following steps (1) to (5):

(1) a step of applying the photoresist composition of the present invention on a substrate,

(2) a step of forming a photoresist film by conducting drying,

(3) a step of exposing the photoresist film to radiation,

(4) a step of baking the exposed photoresist film, and

(5) a step of developing the baked photoresist film with an alkaline developer, thereby forming a photoresist pattern.

The applying of the photoresist composition on a substrate is usually conducted using a conventional apparatus such as spin coater. The photoresist composition is preferably filtrated with filter having 0.2 μm of a pore size before applying. Examples of the substrate include a silicon wafer or a quartz wafer on which a sensor, a circuit, a transistor or the like is formed.

The formation of the photoresist film is usually conducted using a heating apparatus such as hot plate or a decompressor, and the heating temperature is usually 50 to 200° C., and the operation pressure is usually 1 to 1.0*10⁵ Pa.

The photoresist film obtained is exposed to radiation using an exposure system. The exposure is usually conducted through a mask having a pattern corresponding to the desired photoresist pattern. Examples of the exposure source include a light source radiating laser light in a UV-region such as a KrF excimer laser (wavelength: 248 nm), an ArF excimer laser (wavelength: 193 nm) and a F₂ laser (wavelength: 157 nm), and a light source radiating harmonic laser light in a far UV region or a vacuum UV region by wavelength conversion of laser light from a solid laser light source (such as YAG or semiconductor laser).

The temperature of baking of the exposed photoresist film is usually 50 to 200° C., and preferably 70 to 150° C.

The development of the baked photoresist film is usually carried out using a development apparatus. The alkaline developer used may be any one of various alkaline aqueous solution used in the art. Generally, an aqueous solution of tetramethylammonium hydroxide or (2-hydroxyethyl) trimethylammonium hydroxide (commonly known as “choline”) is often used. After development, the photoresist pattern formed is preferably washed with ultrapure water, and the remained water on the photoresist pattern and the substrate is preferably removed.

The photoresist composition of the present invention provides a photoresist pattern showing good Exposure Latitude (EL), and therefore, the photoresist composition of the present invention is suitable for ArF excimer laser lithography, KrF excimer laser lithography, ArF immersion lithography, EUV (extreme ultraviolet) lithography, EUV immersion lithography and EB (electron beam) lithography. Further, the photoresist composition of the present invention can especially be used for ArF immersion lithography, EUV lithography and EB lithography.

### EXAMPLES

The present invention will be described more specifically by Examples, which are not construed to limit the scope of the present invention. The “%” and “part(s)” used to represent the content of any component and the amount of any material to be used in the following Examples are on a weight basis unless otherwise specifically noted.

The analytical condition of liquid chromatography analysis was as followed:

Apparatus: LC-10 A manufactured by SHIMADZU CORPORATION

Column: L column ODS 4.6 mmφ×150 mm

Column temperature: 40° C.

Mobile phase: Liquid A: 5% aqueous acetonitrile solution
Liquid B: acetonitrile

Gradient: 0 min.: Liquid A/Liquid B=70/30
40 min.: Liquid A/Liquid B=0/100
80 min.: Liquid A/Liquid B=0/100 (End of analysis)

Flow rate: 1.0 mL/min.

Injection volume: 10 μL

Detector: UV 235 nm

The analytical condition of Liquid chromatography mass spectroscopy analysis was as followed:

LC apparatus: Agilent 1100 manufactured by Agilent Technologies, Inc.

Column: TSK gel Super HZ column 6 mmφ×150 mm

Mobile phase: tetrahydrofuran

Flow rate: 0.25 mL/min.

Injection volume: 20 μL

Detector: UV 220 nm and 254 nm

### Synthetic Example 1

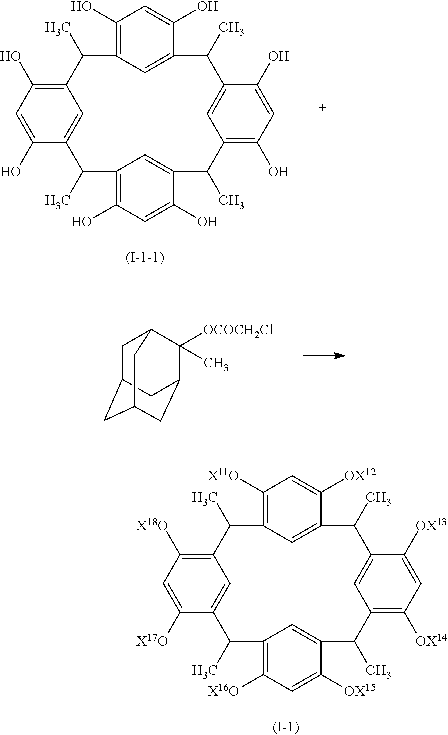

To a solution prepared by dissolving 50.05 parts of a compound represented by the formula (I-1-1) in 500 mL of anhydrous N,N-dimethylformamide, 89.11 parts of 2-methyl-2-adamantyl chloroacetate was added. To the resultant solution, 76.0 parts of potassium carbonate and 3.14 parts of potassium iodide were added, and the resultant mixture was stirred at 75° C. for 8 hours. The reaction mixture was cooled and acidified to pH 5 with 1330 parts of 5% aqueous oxalic acid solution followed by extracting with ethyl acetate. The organic layer obtained was repeated to wash with pure water until the aqueous layer showed neutral, and then, dried over magnesium sulfate. The mixture obtained was filtrated and the filtrate was concentrated under reduced pressure to obtain 125.19 parts of a solid, which is called as I-1.

I-1 was analyzed by liquid chromatography to find out that I-1 contained a compound represented by the formula (I-1) wherein three groups selected from the group consisting of X¹¹, X¹², X¹³, X¹⁴, X¹⁵, X¹⁶, X¹⁷ and X¹⁸ are (2-methyl-2-adamantyloxy)carbonylmethyl groups and the other five groups are hydrogen atoms (hereinafter, simply referred to as COMPOUND (I-1-a)),

a compound represented by the formula (I-1) wherein four selected from the group consisting of X¹¹, X¹², X¹³, X¹⁴, X¹⁵, X¹⁶, X¹⁷ and X¹⁸ are (2-methyl-2-adamantyloxy)carbonylmethyl groups and the other four groups are hydrogen atoms (hereinafter, simply referred to as COMPOUND (I-1-b)), and
a compound represented by the formula (I-1) wherein five selected from the group consisting of X¹¹, X¹², X¹³, X¹⁴, X¹⁵, X¹⁶, X¹⁷ and X¹⁸ are (2-methyl-2-adamantyloxy)carbonylmethyl groups and the other three groups are hydrogen atoms (hereinafter, simply referred to as COMPOUND (I-1-c)).

The content ratio of COMPOUND (I-1-a), COMPOUND (I-1-b) and COMPOUND (I-1-c) in I-1 was followed. Hereinafter, “the content ratio” means a ratio of values of each compounds calculated by a liquid chromatography area percentage method.

COMPOUND (I-1-a):COMPOUND (I-1-b):COMPOUND (I-1-c)=17:76:7 Liquid chromatography mass spectroscopy;

COMPOUND (I-1-a): [M+Na]=1187.6 (C₇₁H₈₆O₁₄=1163.43)

COMPOUND (I-1-b): [M+Na]=392.7 (C₈₄H₁₀₄O₁₆=1369.71)

COMPOUND (I-1-c): [M+Na]=1599.8 (C₉₇H₁₂₂O₁₈=1576.00)

### Synthetic Example 2

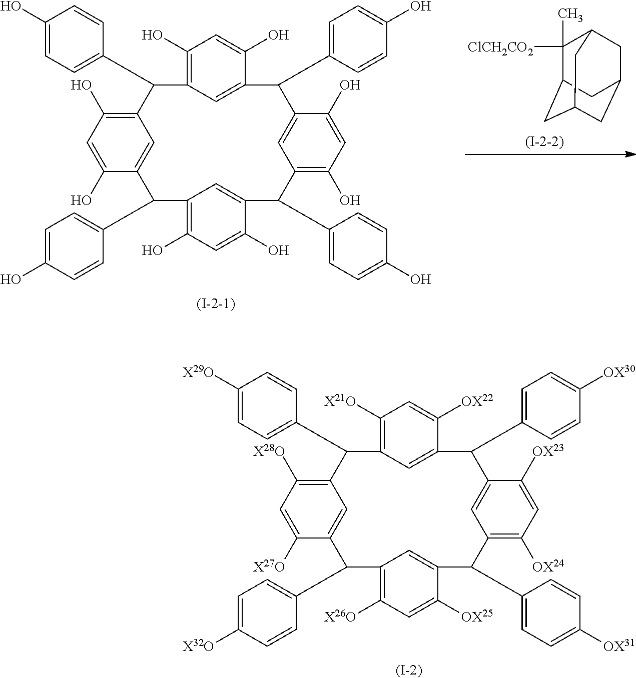

To a solution prepared by dissolving 10.0 parts of a compound represented by the formula (I-2-1) in 100 mL of anhydrous N,N-dimethylformamide, 17.0 parts of 2-methyl-2-adamantyl chloroacetate was added. To the resultant solution, 14.5 parts of potassium carbonate and 0.39 part of potassium iodide were added, and the resultant mixture was stirred at 75° C. for 9 hours. The reaction mixture was cooled and acidified to pH 4 with 500 parts of 4% aqueous oxalic acid solution followed by extracting with ethyl acetate. The organic layer obtained was repeated to wash with pure water until the aqueous layer showed neutral, and then, dried over magnesium sulfate. The mixture obtained was filtrated and the filtrate was concentrated under reduced pressure to obtain 22.3 parts of a solid, which is called as I-2.

I-2 was analyzed by liquid chromatography to find out that I-2 contained a compound represented by the formula (I-2) wherein four groups selected from the group consisting of X²¹, X²², X²³, X²⁴, X²⁵, X²⁶, X²⁷, X²⁸, X²⁹, X³⁰, X³¹ and X³² are (2-methyl-2-adamantyloxy)carbonylmethyl groups and the other eight groups are hydrogen atoms (hereinafter, simply referred to as COMPOUND (I-2-a)),

a compound represented by the formula (I-2) wherein five groups selected from the group consisting of X²¹, X²², X²³, X²⁴, X²⁵, X²⁶, X²⁷, X²⁸, X²⁹, X³⁰, X³¹ and X³² are (2-methyl-2-adamantyloxy)carbonylmethyl groups and the other seven groups are hydrogen atoms (hereinafter, simply referred to as COMPOUND (I-2-b)),
a compound represented by the formula (I-2) wherein six groups selected from the group consisting of X²¹, X²², X²³, X²⁴, X²⁵, X²⁶, X²⁷, X²⁸, X²⁹, X³⁰, X³¹ and X³² are (2-methyl-2-adamantyloxy) carbonylmethyl groups and the other eight groups are hydrogen atoms (hereinafter, simply referred to as COMPOUND (I-2-c)),
a compound represented by the formula (I-2) wherein seven groups selected from the group consisting of X²¹, X²², X²³, X²⁴, X²⁵, X²⁶, X²⁷, X²⁸, X²⁹, X³⁰, X³¹ and X³² are (2-methyl-2-adamantyloxy)carbonylmethyl groups and the other five groups are hydrogen atoms (hereinafter, simply referred to as COMPOUND (I-2-d)), and
a compound represented by the formula (I-2) wherein eight groups selected from the group consisting of X²¹, X²², X²³, X²⁴, X²⁵, X²⁶, X²⁷, X²⁸, X²⁹, X³⁰, X³¹ and X³² are (2-methyl-2-adamantyloxy)carbonylmethyl groups and the other four groups are hydrogen atoms (hereinafter, simply referred to as COMPOUND (I-2-e)).

The content ratio of COMPOUND (I-2-a), COMPOUND (I-2-b), COMPOUND (I-2-c), COMPOUND (I-2-d) and COMPOUND (I-2-e) in I-2 was followed.

COMPOUND (I-2-a):COMPOUND (I-2-b):COMPOUND (I-2-c):COMPOUND (I-2-d):COMPOUND (I-2-e)=8:20:30:28:14 Liquid chromatography mass spectroscopy;

COMPOUND (I-2-a): [M+Na]=1704.0 (C₁₀₄H₁₁₂O₂₀=1681.99)

COMPOUND (I-2-b): [M+Na]=1910.7 (C₁₁₇H₁₃₀O₂₂=1888.27)

COMPOUND (I-2-c): [M+Na]=2116.9 (C₁₃₀H₁₄₈O₂₄=2094.55)

COMPOUND (I-2-d): [M+Na]=2323.0 (C₁₄₃H₁₆₆O₂₆=2300.83)

COMPOUND (I-2-e): [M+Na]=2529.1 (C₁₅₆H₁₈₄O₂₈=2507.11)

Acid generators, quenchers and solvents used in following Examples are followings.

### <Acid Generator>

Acid generator B1:

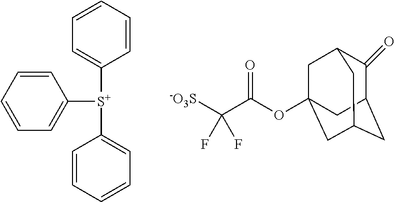

Acid generator B2:

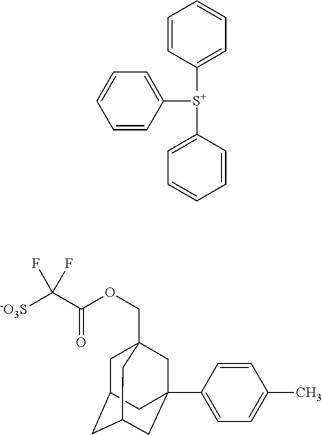

Acid generator B3:

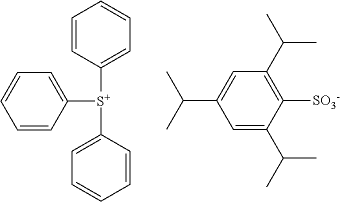

### <Quencher>

Quencher C1: 2,6-diisopropylaniline
Quencher C2: tetrabutylammonium hydroxide
Quencher C3: tetrabutylammonium salicylate
Quencher C4: dicyclohexylmethylamine

### <Solvent>

| | | |
|---|---|---|
| Solvent E1: | propylene glycol monomethyl ether acetate | 400 parts |
| | propylene glycol monomethyl ether | 40 parts |
| | γ-butyrolactone | 5 parts |
| Solvent E2: | propylene glycol monomethyl ether acetate | 400 parts |
| | propylene glycol monomethyl ether | 150 parts |
| | γ-butyrolactone | 5 parts |

### Examples 1 to 4

The following components were mixed to give a solution, and the solution was further filtrated through a fluorine resin filter having a pore diameter of 0.2 μm, to prepare photoresist composition.

COMPOUND (I) (kind and amount are described in Table 1)

Acid generator (kind and amount are described in Table 1)

Quencher (kind and amount are described in Table 1)

Solvent (kind are described in Table 1)

TABLE 1

| | COMPOUND | Acid | Quencher | | | |
|---|---|---|---|---|---|---|
| | (I) (kind/ | generator | (kind/ | | | |
| Ex. | amount | (kind/amount | amount | Solvent | PB | PEB |
| No. | (part)) | (part)) | (part)) | (kind) | (° C.) | (° C.) |
| Ex. 1 | I-1/10 | B1/1.5 | C1/0.07 | E1 | 100 | 100 |
| | | | C2/0.005 | | | |
| Ex. 2 | I-2/10 | B1/1.5 | C1/0.07 | E1 | 100 | 100 |
| | | | C2/0.005 | | | |
| Ex. 3 | I-1/10 | B2/3 | C3/0.15 | E2 | 110 | 110 |
| Ex. 4 | I-1/5 | B2/2 | C3/0.08 | E2 | 110 | 110 |
| | I-2/5 | B3/1 | C4/0.08 | | | |

Silicon wafers were each contacted with hexamethyldisilazane at 90° C. for 60 seconds and each of the photoresist compositions prepared as above was spin-coated over the silicon wafer to give a film thickness after drying of 0.06 μm. After application of each of the photoresist compositions, the silicon wafers thus coated with the respective photoresist compositions were each baked on a direct hotplate at a temperature shown in the column of “PB” in Table 1 for 60 seconds. Using a writing electron beam lithography system (“HL-800D” manufactured by Hitachi, Ltd., accelerating voltage: 50 KeV), each wafer on which the respective photoresist film had been thus formed was exposed to a line and space pattern, while changing stepwise the exposure quantity.

After the exposure, each wafer was subjected to post-exposure baking on a hotplate at a temperature shown in the column of “PEB” in Table 1 for 60 seconds and then to paddle development with an aqueous solution of 2.38% by weight tetramethylammonium hydroxide for 60 seconds.

Each of a pattern developed on the silicon substrate after the development was observed with a scanning electron microscope, and the results of which are shown in Table 2.

Resolution: It is expressed as the exposure amount at which the line width of the line and space pattern became 0.08 pμm when the exposure was conducted with a mask having the line width of the line and space pattern of 0.08 μm.

Line Edge Roughness (LER): The line and space pattern was observed with a scanning electron microscope. The difference between the height of the highest point and height of the lowest point of the scabrous wall surface of the line pattern of which line width was 0.1 μm was measured. When the difference is 5 nm or less, LER is good and its evaluation is marked by “◯”, and when the difference is more than 5 nm, LER is bad and its evaluation is marked by “X”. The smaller the difference is, the better the pattern is.

TABLE 2

| Ex. No. | Resolution (μC) | LER |
|---|---|---|
| Ex. 1 | 44 | ◯ |
| Ex. 2 | 42 | ◯ |
| Ex. 3 | 26 | ◯ |
| Ex. 4 | 60 | ◯ |

Apparent from the results shown in Table 2, photoresist compositions obtained by Examples corresponding to the present invention show good resolution and good line edge roughness.

### Examples 5 and 6

The following components were mixed to give a solution, and the solution was further filtrated through a fluorine resin filter having a pore diameter of 0.2 μm, to prepare photoresist composition.

COMPOUND (I) (kind and amount are described in Table 3)

Acid generator (kind and amount are described in Table 3)

Quencher (kind and amount are described in Table 3)

Solvent (kind are described in Table 3)

TABLE 3

| | COMPOUND (I) | Acid generator | Quencher | |
|---|---|---|---|---|
| | (kind/amount | (kind/amount | (kind/ | Solvent |
| Ex. No. | (part)) | (part)) | amount (part)) | (kind) |
| Ex. 5 | I-1/10 | B1/1.5 | C1/0.07 | E1 |
| | | | C2/0.005 | |
| Ex. 6 | I-2/10 | B1/1.5 | C1/0.07 | E1 |
| | | | C2/0.005 | |

Silicon wafers were each contacted with hexamethyldisilazane at 90° C. for 60 seconds and each of the photoresist compositions prepared as above was spin-coated over the silicon wafer to give a film thickness after drying of 0.06 μm. After application of each of the photoresist compositions, the silicon wafers thus coated with the respective photoresist compositions were each baked on a direct hotplate at 100° C. for 60 seconds. Using an EUV (extreme ultraviolet) exposure system, each wafer on which the respective photoresist film had been thus formed was exposed to a line and space pattern, while changing stepwise the exposure quantity.

After the exposure, each wafer was subjected to post-exposure baking on a hotplate at 100° C. for 60 seconds and then to paddle development with an aqueous solution of 2.38% by weight tetramethylammonium hydroxide for 60 seconds.

Each of a pattern developed on the silicon substrate after the development was observed with a scanning electron microscope, and the results of which are shown in Table 4.

Resolution: It is expressed as the exposure amount at which the line width of the line and space pattern became 0.04 μm when the exposure was conducted with a mask having the line width of the line and space pattern of 0.04 μm.

Line Edge Roughness (LER): The line and space pattern was observed with a scanning electron microscope. The difference between the height of the highest point and height of the lowest point of the scabrous wall surface of the line pattern of which line width was 0.04 μm was measured. When the difference is 5 nm or less, LER is good and its evaluation is marked by “◯”, and when the difference is more than 5 nm, LER is bad and its evaluation is marked by “X”. The smaller the difference is, the better the pattern is.

TABLE 4

| Ex. No. | Resolution (mJ/cm²) | LER |
|---|---|---|
| Ex. 5 | 13.2 | ◯ |
| Ex. 6 | 13.8 | ◯ |

Apparent from the results shown in Table 4, photoresist compositions obtained by Examples corresponding to the present invention show good resolution and good line edge roughness.

What is claimed is:

1. A photoresist composition comprising a compound represented by the formula (I): 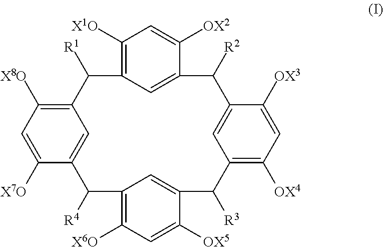
wherein R¹, R², R³ and R⁴ independently represent a hydrogen atom, a C1-C6 alkyl group, a C3-C10 cycloalkyl group, a C4-C20 cycloalkylalkyl group, a C6-C20 aryl group, a C7-C20 aralkyl group or a group represented by —OX⁹, and one or more hydrogen atoms of the alkyl group, the aryl group and the aralkyl group can be replaced by a group represented by —OX¹⁰, X¹, X², X³, X⁴, X⁵ and X⁶, X⁷, X⁸, X⁹ and X¹⁰ independently represent a hydrogen atom or a group represented by the formula (II): 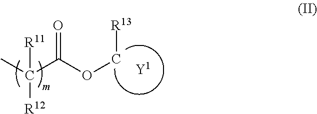
wherein R¹¹ and R¹² independently represent a hydrogen atom or a C1-C6 alkyl group, m represents an integer of 1 to 4, R¹³ represents a C1-C6 alkyl group or a C3-C12 saturated cyclic hydrocarbon group, and ring Y¹ represents a C3-C20 saturated hydrocarbon ring, and an acid generator represented by the formula (B1): 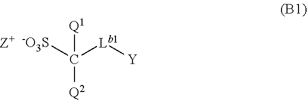
wherein Q¹ and Q² independently represent a fluorine atom or a C1-C6 perfluoroalkyl group, L^{b1} represents a single bond or a C1-C17 saturated divalent hydrocarbon group in which one or more —CH₂— can be replaced by —O— or —CO—, Y represents a C1-C18 aliphatic hydrocarbon group or a C3-C18 saturated cyclic hydrocarbon group, and the aliphatic hydrocarbon group and the saturated cyclic hydrocarbon group can have one or more substituents, and one or more —CH₂— in the aliphatic hydrocarbon group and the saturated cyclic hydrocarbon group can be replaced by —O—, —CO— or —SO₂—, and Z⁺ represents an organic cation.

2. The photoresist composition according to claim 1, wherein at least one selected from the group consisting of X¹, X², X³, X⁴, X⁵, X⁶, X⁷ and X⁸ is the group represented by the formula (II).

3. The photoresist composition according to claim 1, wherein the molecular weight of the compound represented by the formula (I) is 300 to 5,000.

4. A process for producing a photoresist pattern comprising the following steps (1) to (5):
(1) a step of applying the photoresist composition according to claim 1, 2 or 3 onto a substrate,
(2) a step of forming a photoresist film by conducting drying,
(3) a step of exposing the photoresist film to radiation,
(4) a step of baking the exposed photoresist film, and
(5) a step of developing the baked photoresist film with an alkaline developer, thereby forming a photoresist pattern.

5. Use of the photoresist composition according to claim 1, 2 or 3 for producing a photoresist pattern using an electron beam lithography system or an extreme ultraviolet lithography system.
